(19) United States
(12) Patent Application Publication
(10) Pub. No.: US 2009/0053488 A1
(43) Pub. Date: Feb. 26, 2009

(54) ORGANIC ELECTROLUMINESCENCE DEVICE AND METHOD FOR PRODUCING ORGANIC ELECTROLUMINESCENCE DEVICE

(75) Inventors: Yukitoshi JINDE, Sodegaura-shi (JP); Takayasu Sado, Sodegaura-shi (JP); Kiyoshi Ikeda, Sodegaura-shi (JP); Kenichi Fukuoka, Sodegaura-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Idemitsu Kosan Co., Ltd., Chiyoda-ku (JP)

(21) Appl. No.: 11/839,949

(22) Filed: Aug. 16, 2007

(30) Foreign Application Priority Data
Aug. 3, 2007 (JP) 2007-203540

(51) Int. Cl. B32B 7/02; B32B 9/04; C23C 16/00

(52) U.S. Cl. 428/213; 427/248.1; 428/332; 428/690

(57) ABSTRACT

An organic electroluminescence device includes: an anode; a cathode; and a luminescent layer (5) provided between the anode and the cathode. In the organic electroluminescence device, the luminescent layer (5) includes two or more doped regions (51) each of which contains a luminescent dopant, and at least one non-doped region (52) in which no luminescent dopant is contained.

### BACKGROUND OF THE INVENTION

1. Field of the Invention

The present invention relates to an organic electroluminescence device, in particular, to an organic electroluminescence device that is freer from concentration quenching and that can emit light with high efficiency, and to a method of producing the organic electroluminescence device.

2. Description of Related Art

There has been known an organic electroluminescence device (organic EL device) that includes an organic luminescent layer between an anode and a cathode, and that emits light using exciton energy generated by a recombination of a hole and an electron injected into the organic luminescent layer.

In view of advantages as a self-luminous device, such an organic electroluminescence device as described above is expected to serve as a light-emitting device that is excellent in luminous efficiency, image quality and power saving, and favorable for thin designing.

In order to emit light with high efficiency, such a device uses a luminescent layer in which a host is doped with a luminescent dopant (guest).

However, since luminance may be lowered due to concentration quenching in the arrangement where the host is doped with the luminescent dopant, an improvement in efficiency of light emission has been limited (Document: JP-A-2000-340361, paragraphs and [0009]).

A possible method of avoiding concentration quenching is to reduce dopant concentration of the luminescent dopant.

However, a reduction of dopant concentration in a luminescent layer may make it extremely difficult to produce an organic electroluminescence device. For example, in mass-producing a large display or a lighting unit whose light-emitting area is large, it is not possible to control the dopant concentration to be uniformly low all over a light-emitting surface thereof.

### SUMMARY OF THE INVENTION

An object of the present invention is to provide an organic electroluminescence device that: can be easily produced; is freer from concentration quenching; and can emit light with high efficiency, and a method of producing the organic electroluminescence device.

An organic electroluminescence device according to an aspect of the present invention includes: an anode; a cathode; and a luminescent layer provided between the anode and the cathode, in which the luminescent layer includes: two or more doped regions each containing a luminescent dopant; and at least one non-doped region in which the luminescent dopant is not contained.

According to the aspect of the present invention, when a voltage is applied between the anode and the cathode, an electric charge is injected into the luminescent layer.

Consequently, a hole and an electron are recombined to generate excitation energy. The excitation energy is subsequently transferred to the luminescent dopant, whereby light is emitted.

An electric charge recombination occurs in each of the doped regions and the non-doped region(s).

In addition, not only exciton of the non-doped region(s) but also exciton of each of the doped regions transfer energy to the luminescent dopant of each of the doped regions, thereby contributing to light emission.

According to a conventional arrangement, the entire luminescent layer has been doped with a luminescent dopant.

In addition, the dopant concentration thereof has been adjusted to an optimum concentration in order to, for example, secure necessary luminance and necessary luminous efficiency. However, since a higher dopant concentration may cause concentration quenching, the dopant concentration has been required to be extremely lowered so as to avoid the concentration quenching, whereby a production of an organic electroluminescence device has been made difficult.

In this regard, according to the present invention, not only the doped regions but also the non-doped region(s)in which no luminescent dopant is contained are provided.

Providing the non-doped region enables the dopant concentration of the entire luminescent layer to be optimally adjusted, even when the luminescent dopant concentration of each doped region is increased, whereby the organic electroluminescence device can be easily produced.

In addition, even when the non-doped region(s) is provided as described above, excitation energy generated in the non-doped region(s) is transferred to the luminescent dopant of each doped region, thereby contributing to light emission.

Accordingly, high quantum efficiency can be achieved because excitation energy is utilized without deactivation.

In addition, high luminance can also be obtained because the luminescent dopant content of the entire luminescent layer can be secured to be at a desirable level by laminating two or more doped regions.

Although an arrangement in which multiple light-emitting regions are laminated is disclosed in JP-A-06-36877, a layer interposed between the light-emitting regions is a carrier-transport layer. Thus, the layer does not serve as a part of a luminescent layer for providing a field where the electric charge recombination occurs.

Hence, unlike the present invention, such a conventional arrangement does not provide such effects as to lower the dopant concentration of the doped region containing the luminescent dopant in its entirety, or to provide high luminance while preventing concentration quenching by securing a wide region where an exciton is produced.

In addition, U.S. Pat. No. 6,004,685 discloses an organic electroluminescence device that emits red light, according to which a luminescent layer obtained by laminating one doped region layer and one non-doped region layer is used. However, the document does not disclose such a luminescent layer as is described in the present invention. In other words, the document does not disclose the luminescent layer including: two or more doped regions each of which contains a luminescent dopant; and one or more non-doped region(s) in which no luminescent dopant is provided.

An average concentration of the luminescent dopant in the entire luminescent layer is preferably 0.01 mass % or more to 10 mass % or less.

It should be noted that the average concentration of the luminescent dopant in the entire luminescent layer is more preferably 0.01 mass % or more to 1 mass % or less, or still more preferably 0.12 mass % or more to 0.5 mass % or less.

Even when the dopant concentration of the entire layer is 0.01 to 10 mass %, the dopant concentration of each doped region can be increased owing to the presence of a non-doped region in the present invention, whereby the organic electroluminescence device can be easily produced.

In addition, the concentration of the luminescent dopant in each doped region is preferably 0.1 mass % or more to 20 mass % or less.

With this arrangement light emission with high efficiency can be realized with luminous efficiency being prevented from being deteriorated due to concentration quenching.

When the concentration of the luminescent dopant in each doped region is less than 0.1 mass %, a doped region having a uniform concentration may not be easily formed while high luminous efficiency is not obtained. When the concentration of the luminescent dopant in each doped region exceeds 20 mass %, in order to avoid concentration quenching, the thickness of each doped region is required to be reduced so that the dopant concentration of the entire luminescent layer is lowered, thereby making it difficult to produce the organic electroluminescence device. Alternatively, the thickness of each non-doped region is required be increased, so that exciton energy generated in each non-doped region cannot contribute to light emission in each doped region.

It should be noted that the concentration of the luminescent dopant in each doped region is more preferably 0.5 mass % or more to 10 mass % or less, and still more preferably 0.5 mass % or more to 2 mass % or less.

According to the aspect of the present invention, it is preferably that the luminescent dopant includes a substituted or unsubstituted aromatic compound having a fused aromatic ring in which 3 to 15 rings are included.

It should be noted that the fused aromatic ring may include a heterocyclic ring. Any one of such groups as described below can be adopted as the substituent.

When a planar aromatic compound having a large number of rings is used as the luminescent dopant, concentration quenching is likely to occur.

Accordingly, when the compound with which concentration quenching is likely to occur is used as a luminescent dopant, there has been a need to lower the concentration of the luminescent dopant in a luminescent layer.

In the present invention, even when the compound with which concentration quenching is likely to occur is used as the luminescent dopant, the dopant concentration of each doped region can be increased with the non-doped region(s) being provided. Thus, there is no need to precisely control the dopant concentration to be low, and mass productivity of organic electroluminescence devices can be maintained.

According to the aspect of the present invention, it is preferable that the non-doped region(s) be thicker than each of the doped regions.

By setting the thickness of the non-doped region(s) to be larger than that of each doped region, the dopant concentration of the entire luminescent layer can be lowered even when the luminescent dopant concentration of each doped region is high. Therefore, there is no need to control the dopant concentration of the entire luminescent layer to be low, thereby contributing to an improvement in mass productivity of organic electroluminescence devices.

Japanese Patent Application Laid-open No. 2007-35932 discloses an organic electroluminescence device in which a second luminescent layer containing no luminescent dopant is interposed between an electron-transport layer and a first luminescent layer.

However, the above document only discloses an example in which the first luminescent layer is thicker than the second luminescent layer. Such an arrangement is not preferable in order to avoid concentration quenching while doping a luminescent layer with a luminescent dopant at a high concentration.

In contrast, according to the present invention, since the non-doped region(s) is thicker each doped region, even when the dopant concentration of each doped region is increased as described above, the dopant concentration of the entire luminescent layer can be effectively and advantageously lowered, and concentration quenching can be effectively prevented.

According to the aspect of the present invention, it is preferable that the non-doped region(s) has a thickness of 0.1 nm or more to 50 nm or less.

With this arrangement, excitation energy generated in the non-doped region(s) can be transferred to the luminescent dopant of each doped region, thereby improving luminous efficiency.

It should be noted that non-doped region(s) more preferably has a thickness of 0.45 nm or more to 30 nm or less, or still more preferably a thickness of 0.9 nm or more to 15 nm or less.

According to the aspect of the present invention, it is preferable that an affinity level Af_{H} of a host included in each of the doped regions and an affinity level Af_{D} of the luminescent dopant contained in each of the doped regions satisfy the following formula: Af_{D}−Af_{H}≧0.1 eV.

According to the aspect of the present invention, it is preferable that an ionization potential Ip_{H} of a host included in each of the doped regions and an ionization potential Ip_{D} of the luminescent dopant contained in each of the doped regions satisfy the following formula: Ip_{H}−Ip_{D}≧0.1 eV.

When Af_{D} is larger than Af_{H}, the electron is likely to be trapped in the luminescent dopant. On the other hand, when Ip_{H} is larger than Ip_{D}, the hole is likely to be trapped in the luminescent dopant, so that the luminescent dopant serves as an electric charge trap.

When the electric charge is injected in a state where a luminescent dopant that traps the electric charge is uniformly contained in the luminescent layer, electric-charged molecules are uniformly present in the entire luminescent layer. As a result, an injection of an additional electric charge may be impaired by an electric field generated by accumulated electric charge.

In contrast, in the present invention, the non-doped region(s) is provided separately from the doped regions. Accordingly, even when the luminescent dopant that traps the electric charge is used, the electric charge is unevenly distributed to each doped region instead of being uniformly present in the entire luminescent layer, and an unnecessary electric field that may impair the injection of charge is not generated in the non-doped region(s). Thus, good luminous efficiency can be maintained even when the luminescent dopant that traps the electric charge is used.

An affinity level Af (electron affinity) refers to energy that is released or absorbed when one electron is given to a molecule of a material. The affinity level is positive when the energy is released while the affinity level is negative when the energy is absorbed.

The affinity level Af is defined as follows using an ionization potential Ip and an optical energy gap Eg:

Af=Ip−Eg

The ionization potential Ip means energy required for ionizing a compound of each material by removing an electron from the compound, and is a value measured with, for example, an ultraviolet photoelectron spectrophotometer (AC-3, RIKEN KEIKI Co., Ltd.).

The optical energy gap Eg refers to a difference between a conduction level and a valence electron level. The optical energy gap Eg is obtained by, for example, converting into energy a wavelength value for an intersection point of: a tangent at longer wavelengths of an absorption spectrum of a dilute solution of each material in toluene; and a baseline (no absorption).

According to the aspect of the present invention, it is preferable that a host included in each of the doped regions and a host included in the at least one non-doped region have the same composition.

With this arrangement, when the luminescent layer is formed by, for example, vapor deposition, while the luminescent dopant and the host can be deposited when the doped regions are formed, the host alone can be deposited merely by closing a shutter for the luminescent dopant when the non-doped region(s) is formed. In short, production processes for the organic electroluminescence device can be simplified.

According to the aspect of the present invention, it is preferable that the luminescent dopants contained in the doped regions shows different luminescent colors.

For example, when three doped regions respectively containing red, blue and green luminescent dopants are combined, the entire organic electroluminescence device can emit white light.

According to the aspect of the present invention, it is preferable that the luminescent dopant contains a red luminescent dopant that emits red light.

Although the red luminescent dopant capable of emitting red light is generally likely to cause concentration quenching, the dopant concentration of the entire luminescent layer can be lowered due to the presence of the non-doped region(s), such that the dopant concentration of each doped region can be increased. Therefore, even when the red luminescent dopant is used, there is no need to precisely control the dopant concentration of the entire luminescent layer to be low, and mass productivity of organic electroluminescence devices can be maintained.

It should be noted that an example of the red luminescent dopant includes a dopant having a luminous wavelength peak in a range of 540 to 720 nm.

According to the aspect of the present invention, it is preferable that the luminescent dopant contained in each of the doped regions is a compound having one of a fluoranthene skeleton and a perylene skeleton.

According to the aspect of the present invention, it is preferable that the compound having one of a fluoranthene skeleton and a perylene skeleton is an indenoperylene derivative represented by one of the following formulae (1) and (2).

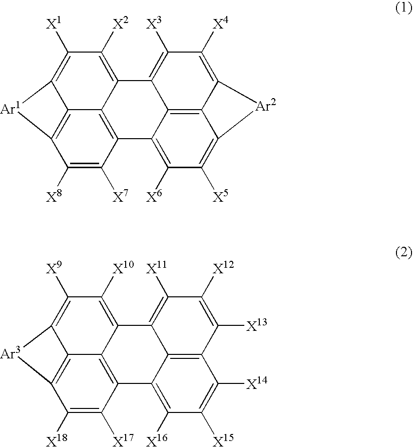

In the formulae (1) and (2): Ar¹, Ar² and Ar³ each represent a substituted or unsubstituted aromatic ring group, or a substituted or unsubstituted aromatic heterocyclic group; X¹ to X¹⁸ each represent a hydrogen atom, a halogen atom, an alkyl group, an alkoxy group, an alkylthio group, an alkenyl group, an alkenyloxy group, an alkenylthio group, an aromatic ring-containing alkyl group, an aromatic ring-containing alkyloxy group, an aromatic ring-containing alkylthio group, an aromatic ring group, an aromatic heterocyclic group, an aromatic ring oxy group, an aromatic ring thio group, an aromatic ring alkenyl group, an alkenyl aromatic ring group, an amino group, a carbazolyl group, a cyano group, a hydroxyl group, —COOR¹′ (R¹′ represents a hydrogen atom, an alkyl group, an alkenyl group, an aromatic ring-containing alkyl group, or an aromatic ring group), —COR²′ (R²′ represents a hydrogen atom, an alkyl group, an alkenyl group, an aromatic ring-containing alkyl group, an aromatic ring group, or an amino group), or —OCOR³′ (R³′ represents an alkyl group, an alkenyl group, an aromatic ring-containing alkyl group, or an aromatic ring group); and adjacent groups of X¹ to X¹⁸ may be bonded to one another to form a ring, or may form a ring together with a substituted carbon atom.

According to the aspect of the present invention, it is preferred that the indenoperylene derivative is a dibenzotetraphenylperiflanthene derivative.

Examples of the indenoperylene derivative include compounds represented by the following formulae (1-1) and (2-1).

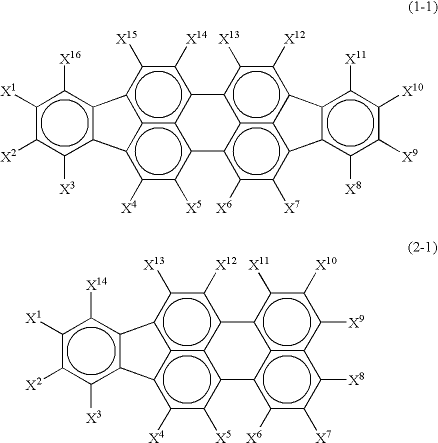

In the above formulae (1-1) and (2-1), X¹ to ¹⁶ each independently represent a hydrogen atom, a linear, branched, or cyclic alkyl group having 1 to 20 carbon atoms, a linear, branched, or cyclic alkoxy group having 1 to 20 carbon atoms, a substituted or unsubstituted aryl group having 6 to 30 carbon atoms, a substituted or unsubstituted aryloxy group having 6 to 30 carbon atoms, a substituted or unsubstituted arylamino group having 6 to 30 carbon atoms, a substituted or unsubstituted alkylamino group having 1 to 30 carbon atoms, a substituted or unsubstituted arylalkylamino group having 7 to 30 carbon atoms, or a substituted or unsubstituted alkenyl group having 8 to 30 carbon atoms. Adjacent substituents and X¹ to X¹⁶ may be bonded to one another to form a cyclic structure. When the adjacent substituents are aryl groups, the substituents may be identical to each other.

It should be noted that the luminescent dopant may be a compound having a fluoranthene skeleton, and examples of the compound having a fluoranthene skeleton include the following compounds.

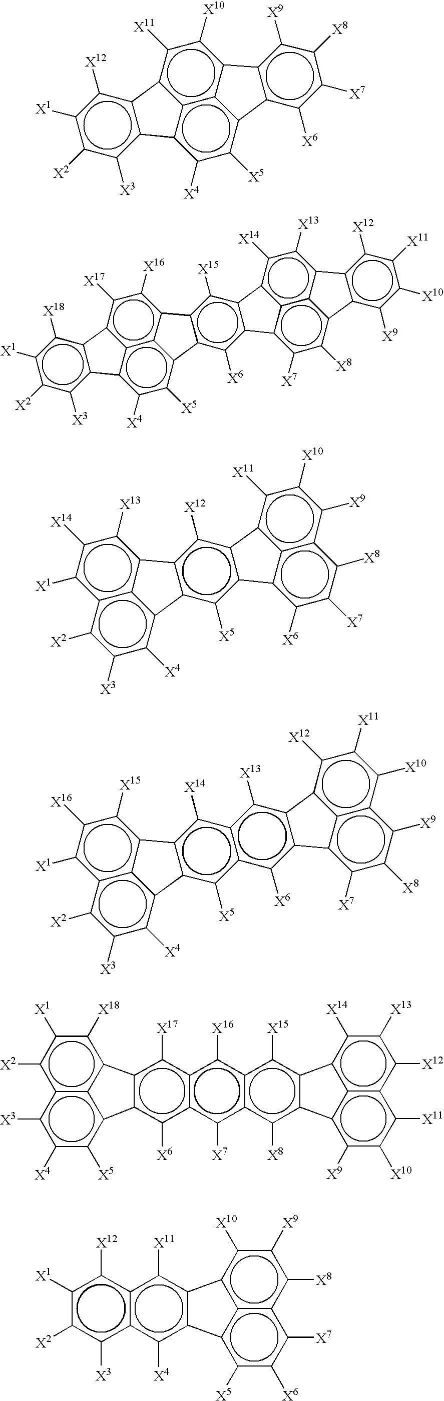

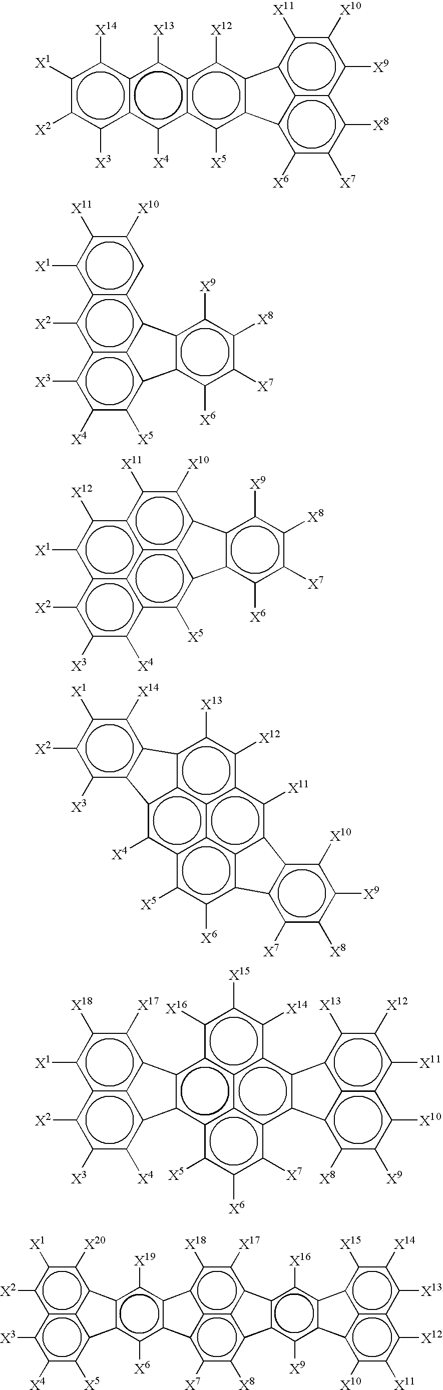

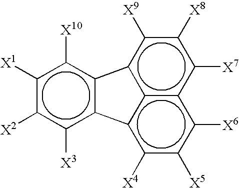

In the above formulae, X¹ to X¹⁶ each independently represent a hydrogen atom, a linear, branched, or cyclic alkyl group having 1 to 20 carbon atoms, a linear, branched, or cyclic alkoxy group having 1 to 20 carbon atoms, a substituted or unsubstituted aryl group having 6 to 30 carbon atoms, a substituted or unsubstituted aryloxy group having 6 to 30 carbon atoms, a substituted or unsubstituted arylamino group having 6 to 30 carbon atoms, a substituted or unsubstituted alkylamino group having 1 to 30 carbon atoms, a substituted or unsubstituted arylalkylamino group having 7 to 30 carbon atoms, or a substituted or unsubstituted alkenyl group having 8 to 30 carbon atoms. Adjacent substituents and X¹ to X¹⁶ may be bonded to one another to form a cyclic structure. When the adjacent substituents are aryl groups, the substituents may be identical to each other.

The compound having a fluoranthene skeleton may have an amino group as represented in each of the following formulae.

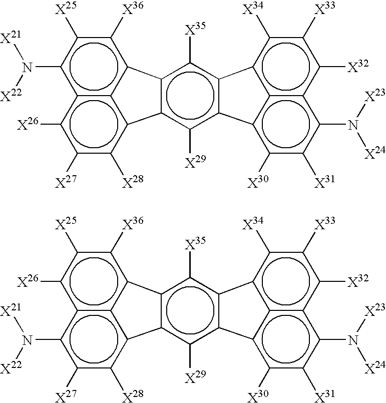

In the above formulae:

X²¹ to X²⁴ each independently represent an alkyl group having 1 to 20 carbon atoms, or a substituted or unsubstituted aryl group having 6 to 30 carbon atoms, and X²¹ and X²² may be bonded to each other through a carbon-carbon bond, —O— or —S—, and/or X²³ and X²⁴ may be bonded to each other through a carbon-carbon bond, —O— or —S—;

X²⁵ to X³⁶ each represent a hydrogen atom, a linear, branched, or cyclic alkyl group having 1 to 20 carbon atoms, a linear, branched, or cyclic alkoxy group having 1 to 20 carbon atoms, a substituted or unsubstituted aryl group having 6 to 30 carbon atoms, a substituted or unsubstituted aryloxy group having 6 to 30 carbon atoms, a substituted or unsubstituted arylamino group having 6 to 30 carbon atoms, a substituted or unsubstituted alkylamino group having 1 to 30 carbon atoms, a substituted or unsubstituted arylalkylamino group having 7 to 30 carbon atoms, or a substituted or unsubstituted alkenyl group having 8 to 30 carbon atoms. Adjacent substituents and X²⁵ to X³⁶ may be bonded to one another to form a cyclic structure.

At least one of the substituents X²⁵ to X³⁶ in each formula preferably contains an amine or alkenyl group.

The compound having a fluoranthene skeleton preferably contains an electron-donating group so that the organic electroluminescence device may obtain high efficiency and a long lifetime, and a preferable electron-donating group is a substituted or unsubstituted arylamino group.

According to the aspect of the present invention, the luminescent dopant, instead of being the compound having one of a fluoranthene skeleton and a perylene skeleton, may be one of a compound having a pyrromethene skeleton represented by the following formula (3) and a metal complex of the compound.

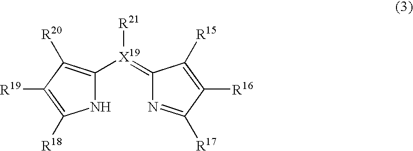

In the above formula (3); at least one of R¹⁵ to R²¹ contains an aromatic ring or forms a fused ring together with an adjacent substituent; the remainder of R¹⁵ to R²¹ are each independently selected from a group consisting of a hydrogen atom, an alkyl group, a cycloalkyl group, an aralkyl group, an alkenyl group, a cycloalkenyl group, an alkynyl group, a hydroxyl group, a mercapto group, an alkoxy group, an alkylthio group, an arylether group, an arylthioether group, an aryl group, a heterocyclic group, a halogen atom, a haloalkane, a haloalkene, a haloalkyne, a cyano group, an aldehyde group, a carbonyl group, a carboxyl group, an ester group, a carbamoyl group, an amino group, a nitro group, a silyl group, a siloxanyl group, and a fused ring or aliphatic ring formed together with an adjacent substituent (each of the groups has 1 to 20 carbon atoms), X¹⁹ representing a carbon atom or a nitrogen atom, R²¹ not being present when X¹⁹ represents a nitrogen atom; and a metal of the metal complex includes at least one metal selected from a group consisting of boron, beryllium, magnesium, chromium, iron, cobalt, nickel, copper, zinc, and platinum.

According to the aspect of the present invention, the luminescent dopant, instead of being the compound having one of a fluoranthene skeleton and a perylene skeleton, is a diketopyrrolopyrrole derivative represented by the following formula (4).

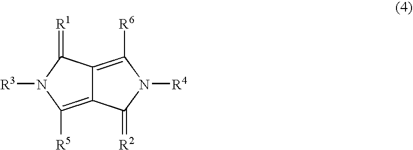

In the above formula (4): R¹ and R² each independently represent an oxygen atom or a nitrogen atom substituted by a cyano group; R³ and R⁴ each independently represent a hydrogen atom, a halogen atom, an alkyl group, an alkenyl group, an aryl group, a heterocyclic group, or COOR⁷ where R⁷ represents an alkyl group, an alkenyl group, an aryl group, or a heterocyclic group; and R⁵ and R⁶ each independently represent an aryl group or a heterocyclic group.

Further, the diketopyrrolopyrrole derivative represented by the above formula (4) is preferably represented by the following formula (4-1).

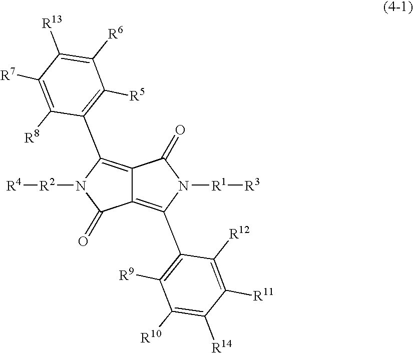

In the above formula (4-1): R¹ and R² each independently represent a substituted or unsubstituted alkylene group; R³ and R⁴ each independently represent a substituted or unsubstituted aliphatic heterocyclic group, or a substituent represented by the following formula (4-2); and R⁵ to R¹⁴ each independently represent a hydrogen atom or a substituent, provided that at least one of R⁵ to R¹⁴ represents an amino group represented by the following formula (4-3).

—X—R¹⁵ (4-2)

In the above formula (4-2), X represents an oxygen atom or a sulfur atom, and R¹⁵ represents a substituted or unsubstituted, monovalent aliphatic hydrocarbon, a substituted or unsubstituted, monovalent aromatic hydrocarbon, or a substituted or unsubstituted, monovalent aromatic heterocyclic group.

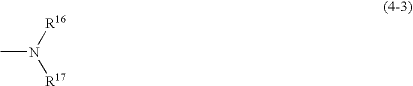

In the above formula (4-3), R¹⁶ and R¹⁷ each independently represent a hydrogen atom, a substituted or unsubstituted, monovalent aliphatic hydrocarbon, a substituted or unsubstituted, monovalent aromatic hydrocarbon, or a substituted or unsubstituted, monovalent aromatic heterocyclic group.

In addition, the diketopyrrolopyrrole derivative represented by the above formula (4) is preferably represented by the following formula (4-4).

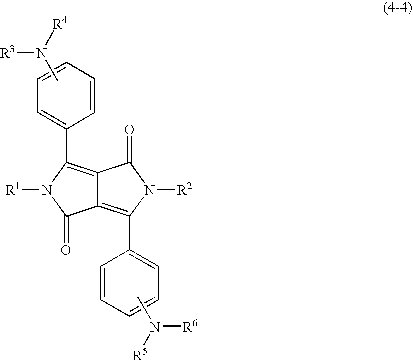

In the above formula (4-4), R¹ to R⁶ each independently represent an alkyl, aryl, or heterocyclic group, each of which may be substituted or unsubstituted.

According to the aspect of the present invention, it is preferable that a host contained in at least one of the doped regions and the at least one non-doped region includes a compound having a fused aromatic ring group having 3 or more carbon rings, the fused aromatic ring group being substituted or unsubstituted.

Further, according to the aspect of the present invention, it is preferable that a host contained in at least one of the doped regions and the at least one non-doped region includes a compound having a fused aromatic ring group having 4 or more carbon rings, the fused aromatic ring group being substituted or unsubstituted.

According to the aspect of the present invention, it is preferable that the host contained in at least one of the doped regions and the at least one non-doped region includes a naphthacene derivative represented by the following formula (5).

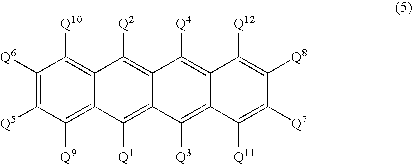

In the above formula (5), Q¹ to Q¹² each independently represent a hydrogen atom, a substituted or unsubstituted alkyl group having 1 to 20 carbon atoms, a substituted or unsubstituted aryl group having 6 to 20 carbon atoms, an amino group, a substituted or unsubstituted alkoxy group having 1 to 20 carbon atoms, a substituted or unsubstituted alkylthio group having 1 to 20 carbon atoms, a substituted or unsubstituted aryloxy group having 6 to 20 carbon atoms, a substituted or unsubstituted arylthio group having 6 to 20 carbon atoms, a substituted or unsubstituted alkenyl group having 2 to 20 carbon atoms, a substituted or unsubstituted aralkyl group having 7 to 20 carbon atoms, or a substituted or unsubstituted heterocyclic group having 5 to 20 atoms, and Q¹ to Q¹² may be identical to or different from one another.

According to the aspect of the present invention, it is preferable that at least one of Q¹, Q², Q³ and Q⁴ in the naphthacene derivative represented by the formula (5) represents an aryl group.

According to the aspect of the present invention, it is preferable that the naphthacene derivative represented by the formula (5) is represented by the following formula (6).

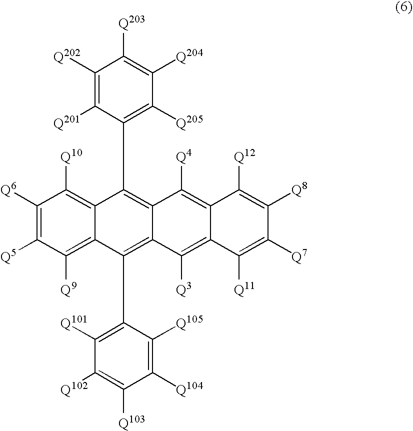

In the above formula (6), Q3 to Q¹², Q¹⁰¹ to Q¹⁰⁵, and Q²⁰¹ to Q²⁰⁵ each independently represent a hydrogen atom, a substituted or unsubstituted alkyl group having 1 to 20 carbon atoms, a substituted or unsubstituted aryl group having 6 to 20 carbon atoms, an amino group, a substituted or unsubstituted alkoxy group having 1 to 20 carbon atoms, a substituted or unsubstituted alkylthio group having 1 to 20 carbon atoms, a substituted or unsubstituted aryloxy group having 6 to 20 carbon atoms, a substituted or unsubstituted arylthio group having 6 to 20 carbon atoms, a substituted or unsubstituted alkenyl group having 2 to 20 carbon atoms, a substituted or unsubstituted aralkyl group having 7 to 20 carbon atoms, or a substituted or unsubstituted heterocyclic group having 5 to 20 atoms, and Q³ to Q¹², Q¹⁰¹ to Q¹⁰⁵, and Q201 to Q205 may be identical to or different from one another.

More preferably, at least one of Q¹⁰¹, Q¹⁰⁵, Q²⁰¹ and Q²⁰⁵ in the naphthacene derivative represented by the formula (6) represents an alkyl group, an aryl group, an amino group, an alkoxy group, an aryloxy group, an alkylthio group, an arylthio group, an alkenyl group, an aralkyl group, or a heterocyclic group, and Q¹⁰¹, Q¹⁰⁵, Q²⁰¹ and Q²⁰⁵ are identical to or different from one another.

Examples of the naphthacene derivative include the following derivatives.

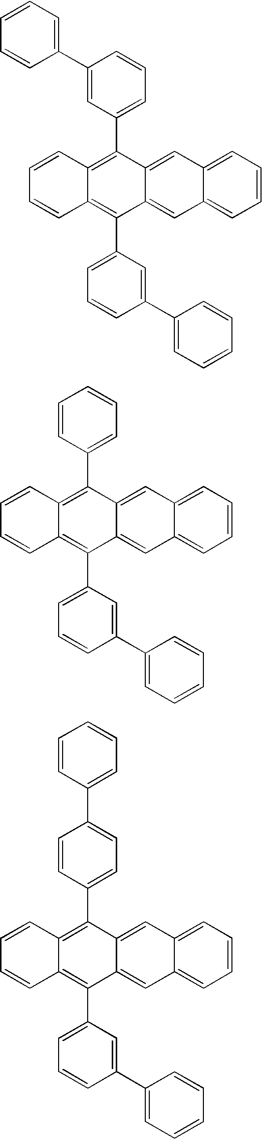

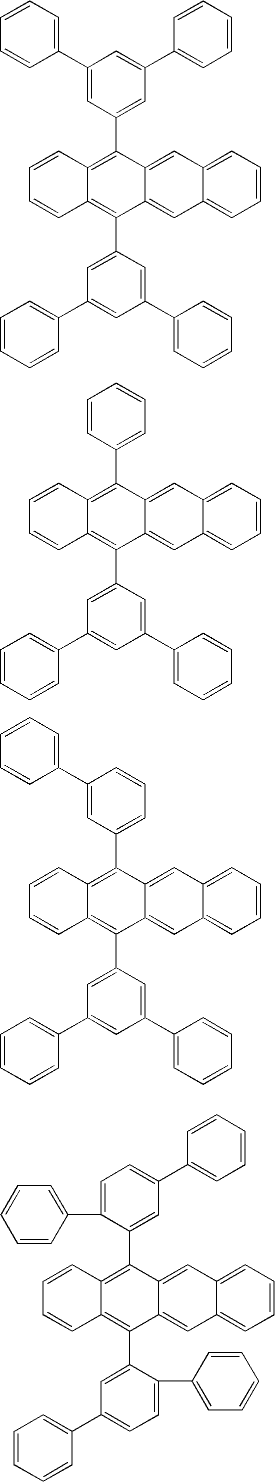

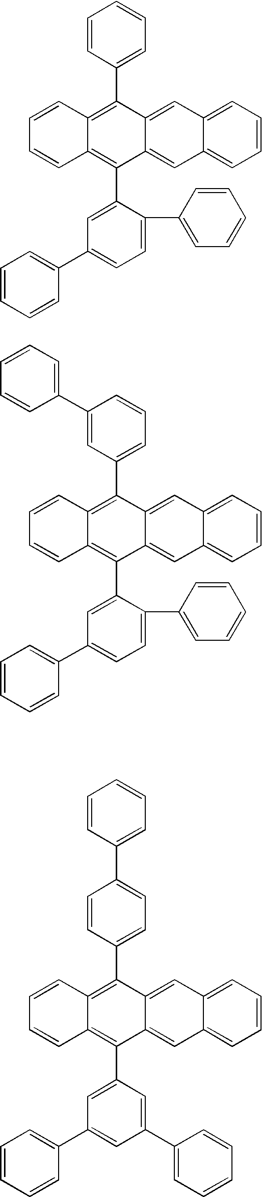

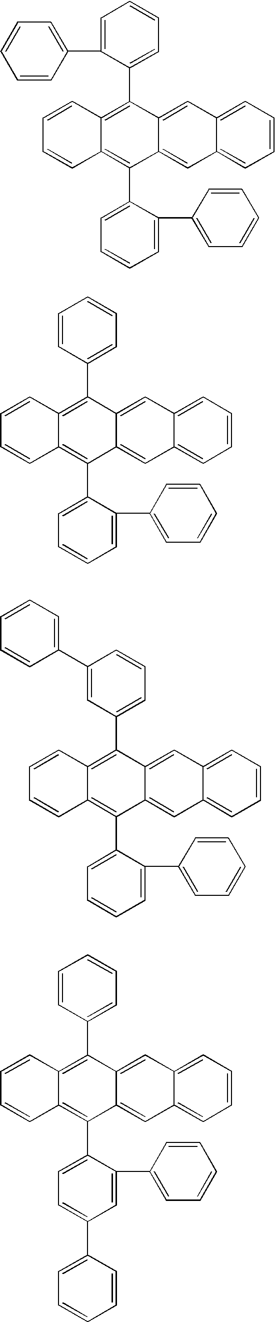

According to the aspect of the present invention, it is preferable that the host contained in at least one of the doped regions and the at least one non-doped region includes a compound represented by the following formula (7).

X—(Y)ₙ (7)

In the above formula (7): X represents a fused aromatic ring group having 3 or more carbon rings; Y represents a group selected from a group consisting of a substituted or unsubstituted aryl group, a substituted or unsubstituted diarylamino group, a substituted or unsubstituted arylalkyl group, and a substituted or unsubstituted alkyl group; and n represents an integer in a range of 1 to 6, and when n represents 2 or more, Ys may be identical to or different from each other.

X preferably represents a group containing one or more skeleton(s) selected from a group consisting of naphthacene, pyrene, anthracene, perylene, chrysene, benzoanthracene, pentacene, dibenzoanthracene, benzopyrene, benzofluorene, fluoranthene, benzofluoranthene, naphthylfluoranthene, dibenzofluorene, dibenzopyrene, dibenzofluoranthene, and acenaphthylfluoranthene. More preferably, X represents a group containing a naphthacene skeleton or an anthracene skeleton.

Y preferably represents an aryl or diarylamino group having 12 to 60 carbon atoms, or more preferably represents an aryl group having 12 to 20 carbon atoms, or a diarylamino group having 12 to 40 carbon atoms. n preferably represents 2.

According to the aspect of the present invention, it is preferable that the compound represented by the formula (7) is an anthracene derivative represented by the following formula (8).

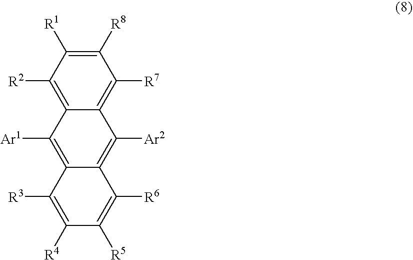

In the above formula (8), Ar¹ and Ar² each independently represent a group derived from a substituted or unsubstituted aromatic ring having 6 to 20 carbon atoms, the aromatic ring being substituted by at least one substituent or unsubstituted, the at least one substituent being selected from a group consisting of a substituted or unsubstituted aryl group having 6 to 50 carbon atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, and a hydroxy group, two or more substituents being identical to or different from each other when the aromatic ring is substituted by the two or more substituents, adjacent substituents being bonded to each other to form a saturated or unsaturated cyclic structure or not being bonded to each other.

R¹ to R⁸ are each selected from a group consisting of a hydrogen atom, a substituted or unsubstituted aryl group having 6 to 50 carbon atoms, a substituted or unsubstituted heteroaryl group having 5 to 50 atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, and a hydroxy group, adjacent substituents being bonded to each other to form a saturated or unsaturated cyclic structure or not being bonded to each other.

Specific examples of the anthracene derivative include such compounds as shown in FIGS. 1 and 2.

In addition, the anthracene derivative represented by the above formula (8) is preferably, for example, an asymmetric anthracene derivative represented by the following formula (8-1).

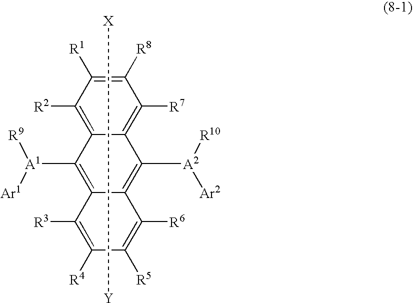

In the above formula (8-1), A¹ and A² each independently represent a hydrogen atom, or a substituted or unsubstituted aromatic ring group having 6 to 50 carbon atoms;

R¹ to R¹⁰ are each independently selected from a hydrogen atom, a substituted or unsubstituted aromatic ring group having 6 to 50 carbon atoms, a substituted or unsubstituted aromatic heterocyclic group having 5 to 50 atoms, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, or a hydroxyl group.

Each Ar¹, Ar², R⁹ and R¹⁰ may be plural, and adjacent groups may form a saturated or unsaturated cyclic structure.

However, in the above formula (8-1), groups symmetric with respect to the X-Y axis shown on central anthracene are not bound to 9- and 10-positions of the anthracene.

Examples of the asymmetric anthracene derivative include such derivatives as shown in FIGS. 3 to 8.

In addition, the anthracene derivative represented by the above formula (8) may be a bisanthracene derivative represented by the following formula (8-2).

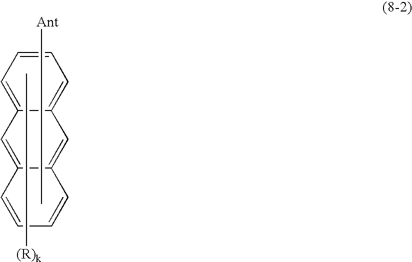

In the above formula (8-2):

Ant represents an anthracene derivative which may be substituted;

R is selected from a hydrogen atom, a substituted or unsubstituted aryl group having 6 to 50 carbon atoms, a substituted or unsubstituted heteroaryl group having 5 to 50 atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, and a hydroxy group. Adjacent substituents may be bonded to each other to form a saturated or unsaturated cyclic structure; and

k represents an integer in a range of 0 to 9.

Examples of the bisanthracene derivative include compounds 2a-41 to 2a-48 described above shown in FIG. 2, and the following compounds shown in FIGS. 9 and 10.

It should be noted that, according to the present invention, each of the host contained in each doped region and the host contained in the non-doped region(s) may be formed of one kind of a host material, or may be formed of multiple kinds of host materials.

A method of producing an organic electroluminescence device according to another aspect of the present invention is a method that uses a vapor deposition apparatus that includes: a plurality of vapor deposition sources; and shutters that shield transpiration of a vapor deposition material from the deposition sources, the method including steps of: setting in at least one of the deposition sources a dopant material that forms the luminescent dopant, and setting in at least one of the other deposition sources a host material that forms hosts of the doped regions and a host of the at least one non-doped region; heating the at least one of the deposition sources in which the dopant material is set and the at least one of the other deposition sources in which the host material is set; and opening and closing the shutter to form the doped regions and the at least one non-doped region.

According to the production method, both the host material and the dopant material are deposited when the shutter is opened, such that the doped region in which the host is doped with the luminescent dopant is formed. On the other hand, the transpiration of the dopant material is shielded when the shutter is closed, such that the host material alone is deposited and a non-doped region is formed.

Accordingly, the doped region and the non-doped region can be alternately formed merely by repeatedly opening and closing the shutter, whereby forming processes of the luminescent layer can be simplified. Consequently, the above-mentioned organic electroluminescence device that is freer from concentration quenching and that can emit light with high efficiency can be easily produced.

### BRIEF DESCRIPTION OF THE DRAWINGS

FIG. 1 is an illustration showing specific examples of an anthracene derivative used as a host of a doped region according to the present invention;

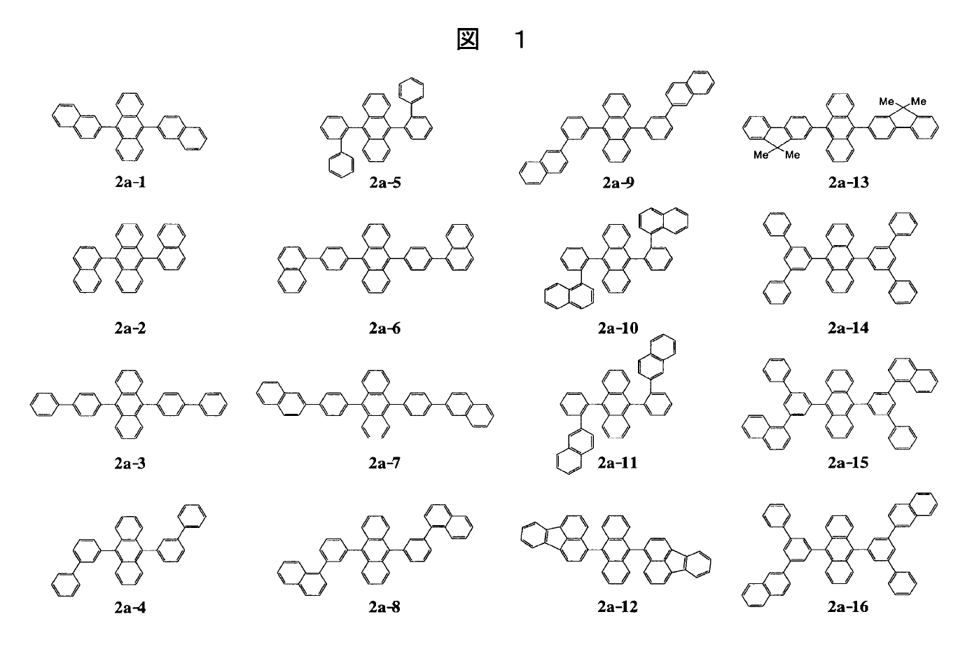

FIG. 2 is an illustration showing specific examples of the anthracene derivative used as the host of the doped region according to the present invention;

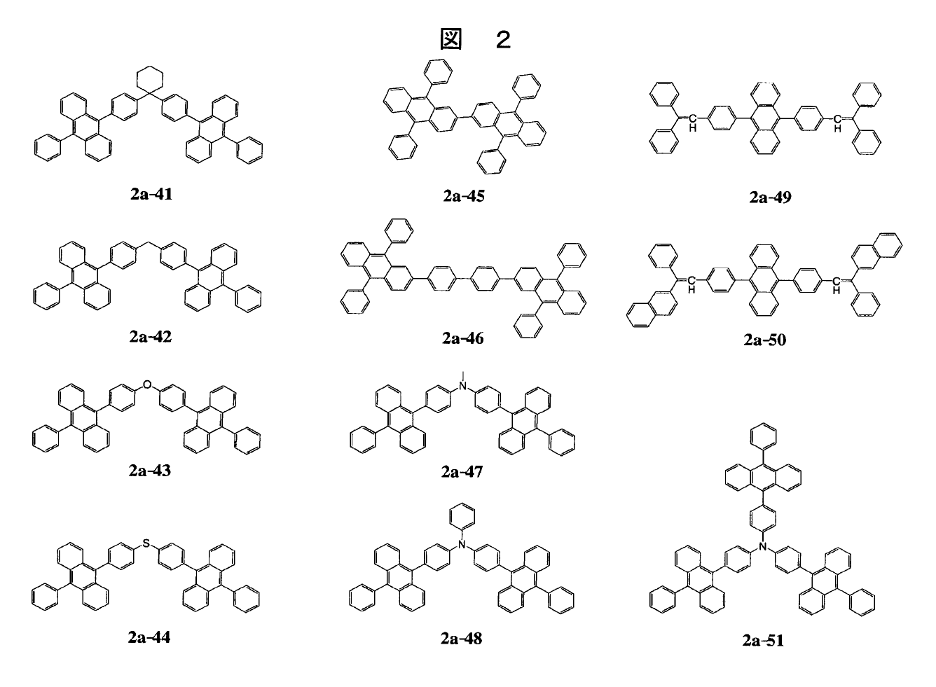

FIG. 3 is an illustration showing specific examples of the anthracene derivative used as the host of the doped region according to the present invention;

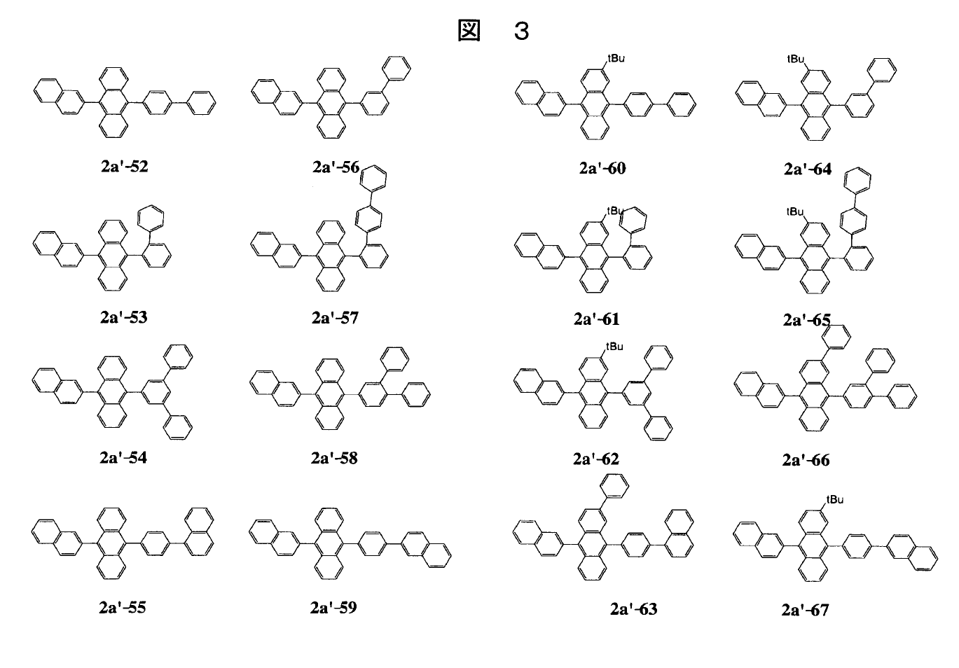

FIG. 4 is an illustration showing specific examples of the anthracene derivative used as the host of the doped region according to the present invention;

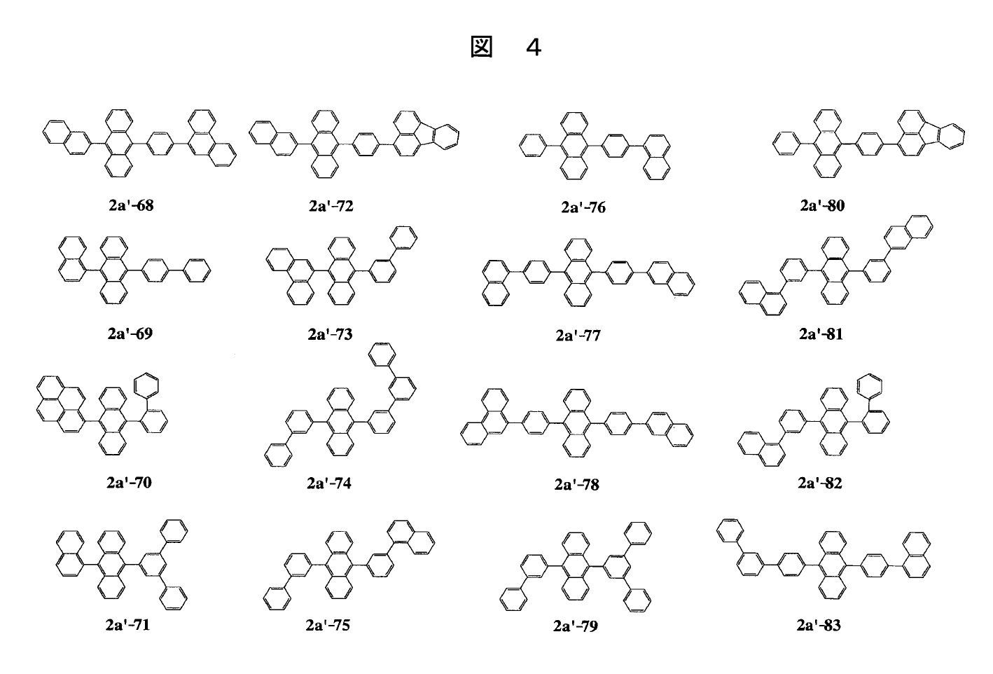

FIG. 5 is an illustration showing specific examples of the anthracene derivative used as the host of the doped region according to the present invention;

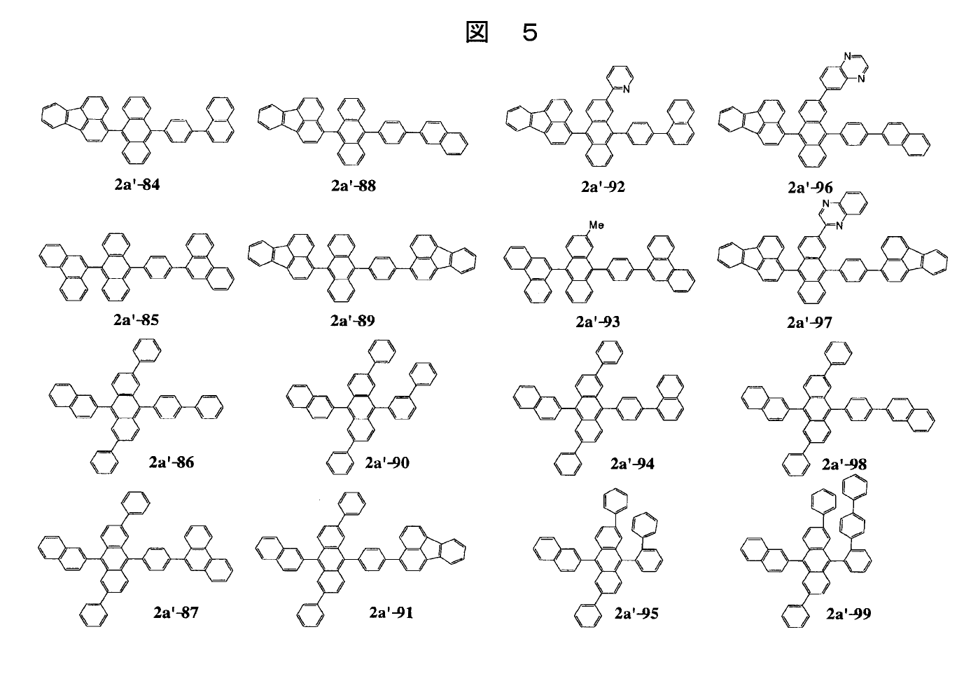

FIG. 6 is an illustration showing specific examples of the anthracene derivative used as the host of the doped region according to the present invention;

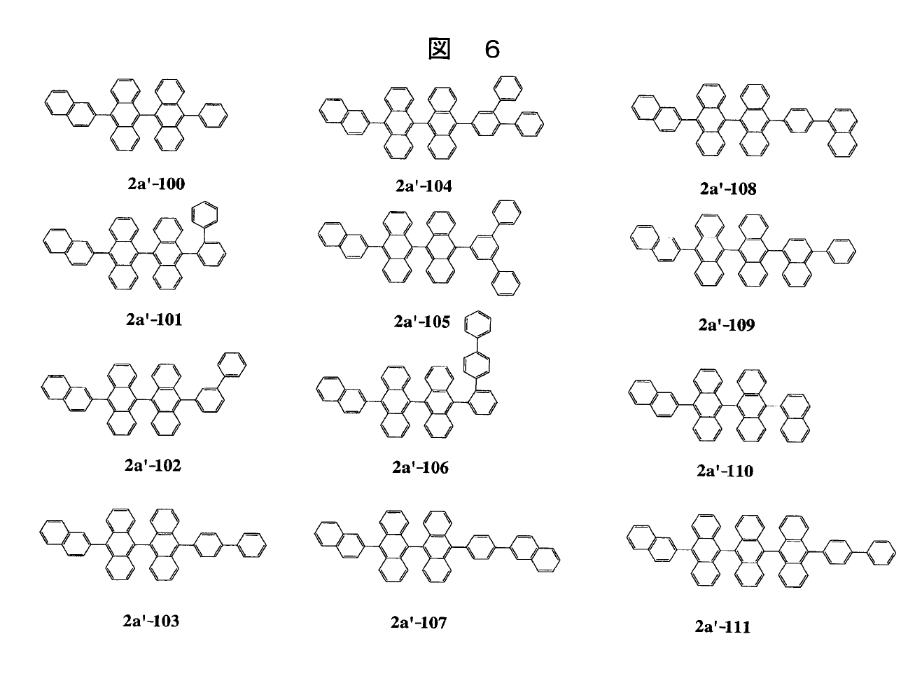

FIG. 7 is an illustration showing specific examples of the anthracene derivative used as the host of the doped region according to the present invention;

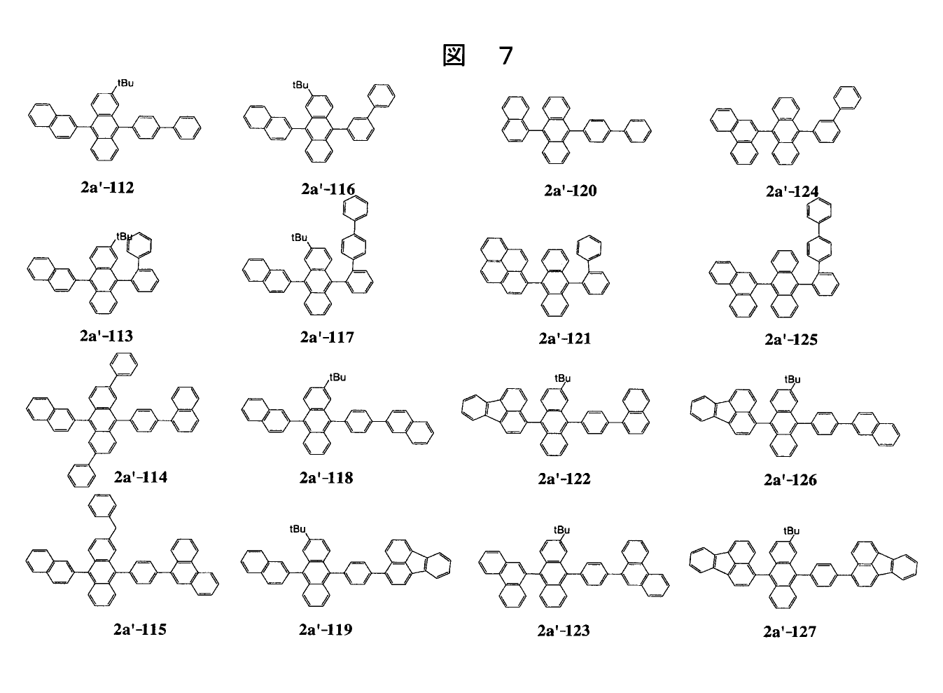

FIG. 8 is an illustration showing specific examples of the anthracene derivative used as the host of the doped region according to the present invention;

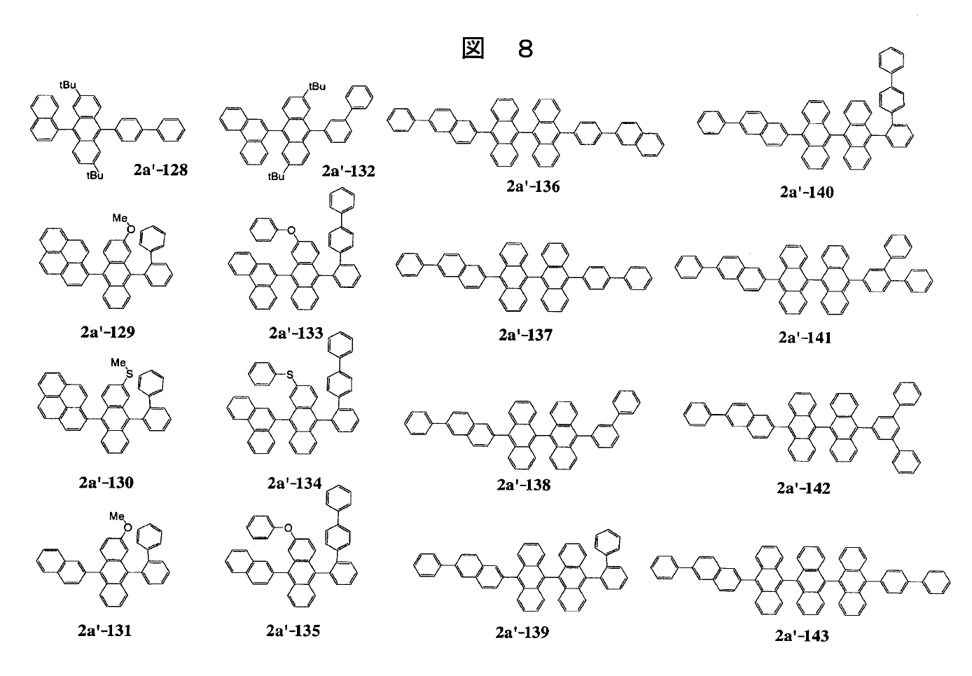

FIG. 9 is an illustration showing specific examples of the anthracene derivative used as the host of the doped region according to the present invention;

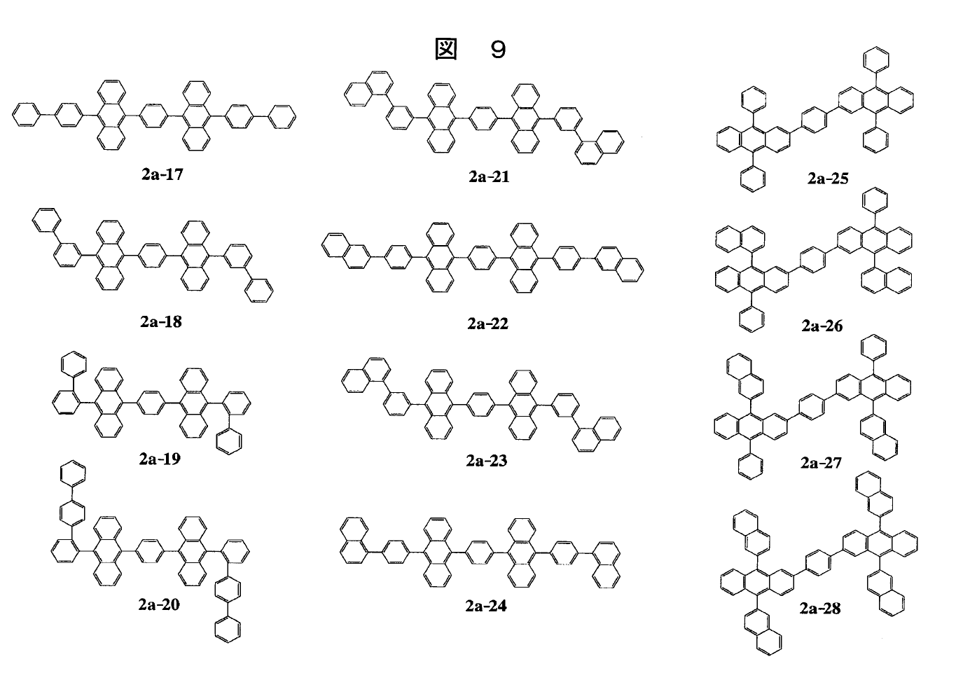

FIG. 10 is an illustration showing specific examples of the anthracene derivative used as the host of the doped region according to the present invention;

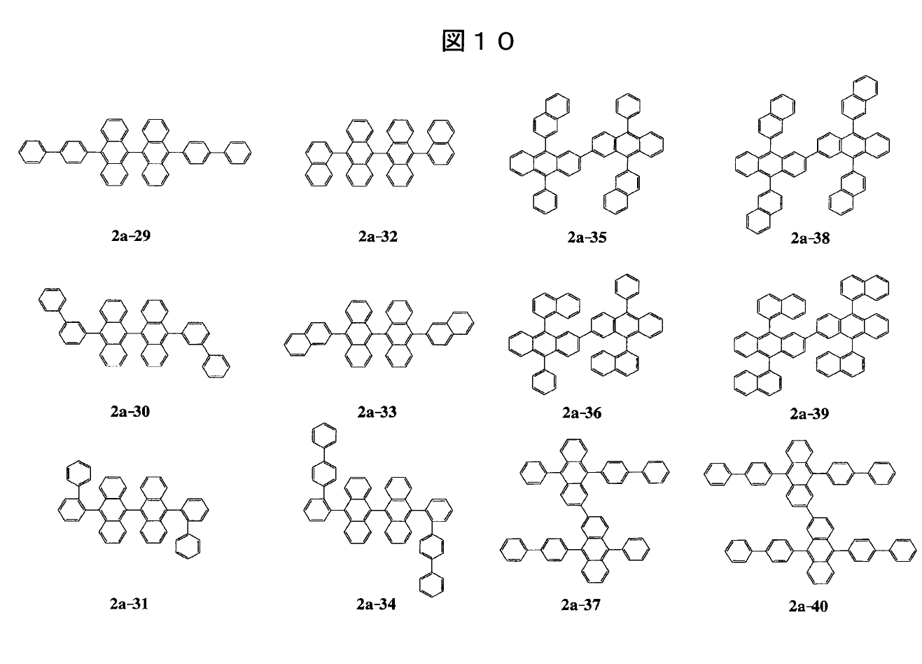

FIG. 11 is an illustration schematically showing an overall arrangement of an organic electroluminescence device according to an embodiment of the present invention;

FIG. 12 is an illustration showing a luminescent layer of the organic electroluminescence device according to the embodiment of the present invention;

FIG. 13 is an illustration showing the luminescent layer of the organic electroluminescence device according to the embodiment of the present invention;

FIG. 14 is an illustration showing the luminescent layer of the organic electroluminescence device according to the embodiment of the present invention; and

FIG. 15 is an illustration showing a deposition apparatus used for producing the organic electroluminescence device according to the embodiment of the present invention.

### DETAILED DESCRIPTION OF PREFERRED EMBODIMENT(S)

Preferred embodiments of the present invention will be described below.

### [Arrangement of Organic Electroluminescence Device]

Representative arrangement examples of an organic electroluminescence device used in the present invention are shown below. As a matter of course, the present invention is not limited to these examples.

The organic electroluminescence device may be arranged to include:

(1) anode/luminescent layer/electron transport layer/cathode;

(2) anode/hole transport layer/luminescent layer/electron transport layer/cathode;

(3) anode/hole injection layer/hole transport layer/luminescent layer/electron transport layer/cathode;

(4) anode/hole transport layer/luminescent layer/electron transport layer/electron injection layer/cathode;

(5) anode/hole injection layer/hole transport layer/luminescent layer/electron transport layer/electron injection layer/cathode;

(6) anode/insulating layer/hole transport layer/luminescent layer/electron transport layer/cathode;

(7) anode/hole transport layer/luminescent layer/electron transport layer/insulating layer/cathode;

(8) anode/insulating layer/hole transport layer/luminescent layer/electron transport layer/insulating layer/cathode;

(9) anode/hole injection layer/hole transport layer/luminescent layer/electron transport layer/insulating layer/cathode;

(10) anode/insulating layer/hole injection layer/hole transport layer/luminescent layer/electron transport layer/electron injection layer/cathode; or

(11) anode/insulating layer/hole injection layer/hole transport layer/luminescent layer/electron transport layer/electron injection layer/insulating layer/cathode.

Of the above examples, use of the arrangement (2), (3), (4), (5), (8), (9) or (11) is generally preferable.

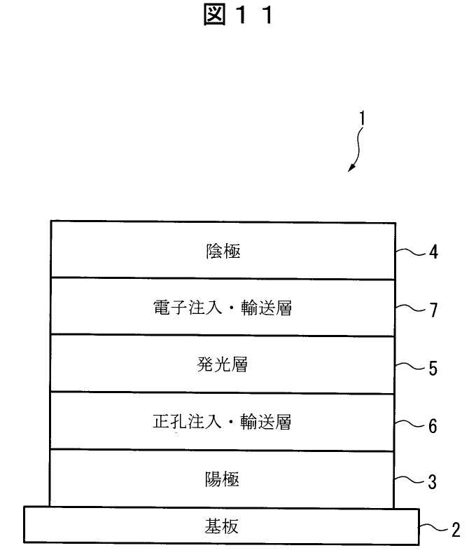

For example, the organic electroluminescence device of this embodiment may be arranged as in the above arrangement example (5), the overall arrangement of which is schematically shown in FIG. 11.

An organic electroluminescence device 1 has a transparent substrate 2, an anode 3, a cathode 4, and a luminescent layer 5 disposed between the anode 3 and the cathode 4.

As shown in FIG. 11, in the organic electroluminescence device 1, a hole injection/transport layer 6 is exemplarily provided between the luminescent layer 5 and the anode 3, and an electron injection/transport layer 7 is exemplarily provided between the luminescent layer 5 and the cathode 4.

In addition, an electron-blocking layer may be provided on a side of the luminescent layer 5 close to the anode 3, and a hole-blocking layer may be provided on the side of the luminescent layer 5 close to the cathode 4.

With this arrangement, an electron or a hole can be trapped in the luminescent layer 5, such that a probability of an exciton generation in the luminescent layer 5 can be increased.

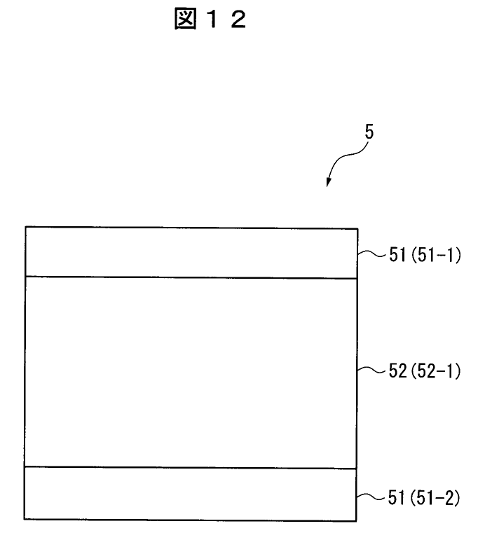

FIG. 12 schematically shows an arrangement of the luminescent layer 5.

The luminescent layer 5 has: two or more doped regions 51 in each of which a luminescent dopant is contained; and one or more non-doped region(s) 52 in each of which no luminescent dopant is contained.

Here, the non-doped region(s) 52 is (are) thicker than each of the doped regions 51.

Although FIG. 12 exemplifies a luminescent layer 5 provided with two doped regions 51 (51-1 and 51-2) and one non-doped region 52 (52-1), the arrangement of the luminescent layer 5 is not limited thereto.

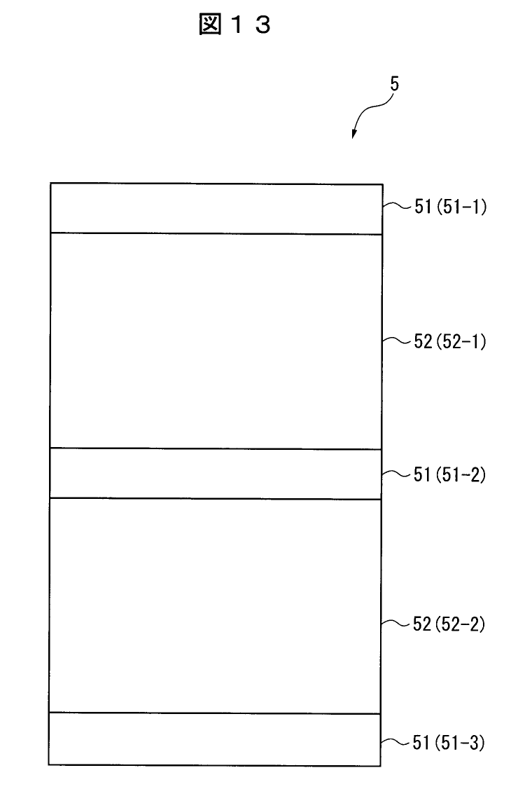

For example, as shown in FIG. 13, the layer may have three doped regions 51 and two non-doped regions 52.

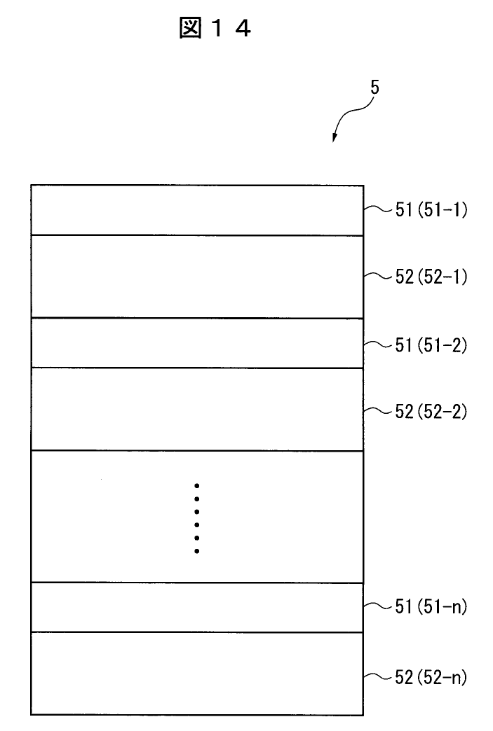

In addition, the luminescent layer 5 may be arranged as shown in FIG. 14.

In FIG. 14, the luminescent layer 5 includes the n doped regions 51 and n non-doped regions 52, both of which are alternately laminated.

Although a method of forming the luminescent layer 5 is not particularly limited, the layer may be formed by, for example, a vapor deposition method.

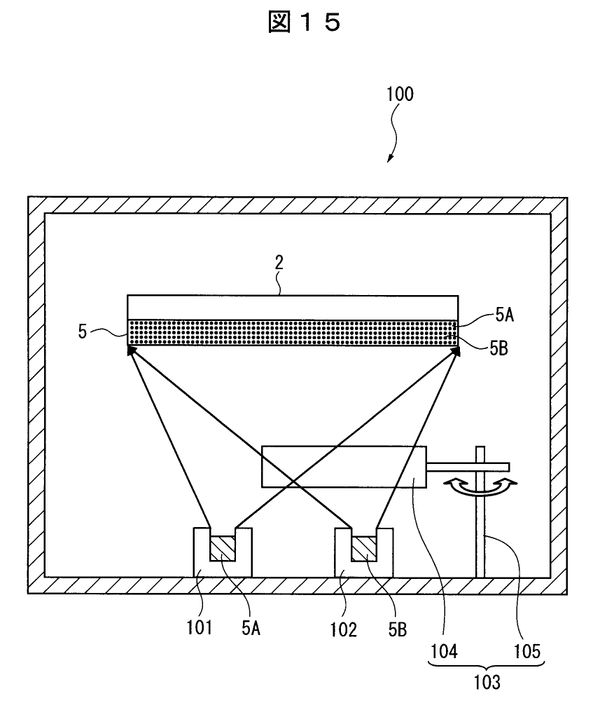

For example, a deposition apparatus 100 shown in FIG. 15 can be used for forming the luminescent layer 5.

The deposition apparatus 100 includes: multiple deposition sources 101 and 102; and a shutter 103 for shielding transpiration of a deposition material from the deposition source 102. The shutter 103 has: a shield 104 positioned above the deposition source 102 to shield the transpiration of the deposition material from the deposition source 102; and a rotary shaft 105 for rotatably supporting the shield 104.

The shield 104 is removed from the position above the deposition source 102 by rotating the rotary shaft 105 to let out the transpiration. Conversely, the shield 104 is returned to the position above the deposition source 102 to shield the transpiration. In other words, the shutter 103 can be opened or closed by rotating the rotary shaft 105.

In forming the luminescent layer 5, the substrate 2 is initially placed at an upper portion in the deposition apparatus 100, a dopant material 5B for forming the luminescent dopant is set in the deposition source 102, and a host material 5A for forming the host is set in the deposition source 101. It should be noted that the illustrations of the anode 3 and the hole injection/transport layer 6 are omitted in FIG. 15.

Although both the deposition sources 101 and 102 are heated at the time of deposition, the doped regions 51 and the non-doped region(s) 52 can be separately formed by opening and closing the shutter 103.

Specifically, in forming the doped regions 51, the host material 5A and the dopant material 5B are evaporated by opening the shutter 103. On the other hand, in forming the non-doped region(s) 52, only the host material 5A is evaporated by closing the shutter 103.

For example, when the luminescent layer 5 shown in FIG. 12 is formed, the host material 5A and the dopant material 5B are initially evaporated by opening the shutter 103 to form the doped region 51-1. Subsequently, only the host material 5A is evaporated by closing the shutter 103 to form the non-doped region 52. Finally, the doped region 51-2 is formed by opening the shutter 103.

It should be noted that an illustration of a laminated structure of the luminescent layer 5 is omitted in FIG. 15. In actuality, the luminescent layer 5 has the laminated structure as shown in each of FIGS. 12 to 14.

As described above, the luminescent layer 5 can be easily formed merely by repeating steps of forming the doped regions 51 and the non-doped regions 52. However, for example, when the shutter 103 is set to be automatically opened or closed, a terminal of the luminescent layer 5 may be the doped region 51, or may be the non-doped region 52 depending on a timing of deposition termination.

In either case, since the doped region 51-n is adjacent at least to the non-doped region 52-(n−1), energy can be transferred from the non-doped region 52-(n−1). Accordingly, a region where an exciton is generated can be secured to be wide, and the dopant concentration of the entire luminescent layer 5 can be properly adjusted even when the dopant concentration of the doped region 51-n is high. Therefore, the effects and advantages according to the present invention can be obtained all the same.

Although all the doped regions 51 are compounded the same while all the non-doped regions 52 are compounded the same in the above described exemplary arrangement, the multiple doped regions 51 or the multiple non-doped regions 52 included in the luminescent layer 5 may be differently compounded from each other.

Although the present invention can provide a significant effect when a luminescent color of the luminescent dopant is red, the luminescent color is not limited thereto but may be, for example, blue or green.

Examples of the doping material which can be used as a blue or green luminescent dopant may include but not be limited to arylamine compounds and/or styrylamine compounds, anthracene, naphthalene, phenanthrene, pyrene, tetracene, coronene, chrysene, fluoresceine, perylene, phthaloperylene, naphthaloperylene, perynone, phthaloperynone, naphthaloperynone, diphenylbutadiene, tetraphenylbutadiene, coumarin, oxadiazole, aldazine, bisbenzoxazoline, bisstyryl, pyrazine, cyclopentadiene, quinoline metal complexes, aminoquinoline metal complexes, benzoquinoline metal complexes, imine, diphenylethylene, vinylanthracene, diaminocarbazole, pyrane, thiopyrane, polymethine, merocyanine, imidazole-chelated oxynoid compounds, quinacridone, rubrene, and fluorescent dyes.

In addition, in the organic electroluminescence device according to the present invention, the blue or green luminescent dopant preferably contains an aryl amine compound and/or a styrylamine compound.

Examples of the arylamine compound include compounds each represented by the following formula (A), and examples of the styrylamine compound include compounds each represented by the following formula (B).

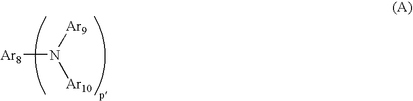

In the formula (A), Ar₈ represents a group selected from phenyl, biphenyl, terphenyl, stilbene, and distyrylaryl groups. Ar₉ and Ar₁₀ each represent a hydrogen atom or an aromatic group having 6 to 20 carbon atoms, and each of Ar₉ and Ar¹⁰ may be substituted. p′ represents an integer in a range of 1 to 4. Ar₉ and/or Ar₁₀ are/is more preferably substituted by styryl group(s).

Here, the aromatic group having 6 to 20 carbon atoms is preferably a phenyl group, a naphthyl group, an anthracenyl group, a phenanthryl group, a terphenyl group, or the like.

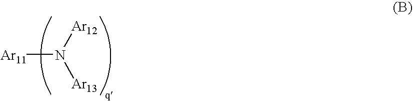

In the above formula (B), Ar₁₁ to Ar¹³ each represent an aryl group having 5 to 40 carbon atoms, each of which may be substituted while q′ represents an integer in a range of 1 to4.

Here, examples of the aryl group having 5 to 40 atoms preferably include phenyl, naphthyl, anthracenyl, phenanthryl, pyrenyl, coronyl, biphenyl, terphenyl, pyrrolyl, furanyl, thiophenyl, benzothiophenyl, oxadiazolyl, diphenylanthracenyl, indolyl, carbazolyl, pyridyl, benzoquinolyl, fluoranthenyl, acenaphthofluoranthenyl, and stilbene. In addition, the aryl group having 5 to 40 atoms may be substituted by a substituent. Examples of the substituent preferably include: an alkyl group having 1 to 6 carbon atoms such as an ethyl group, a methyl group, an isopropyl group, an n-propyl group, an s-butyl group, a t-butyl group, a pentyl group, a hexyl group, a cyclopentyl group, or a cyclohexyl group; an alkoxy group having 1 to 6 carbon atoms such as an ethoxy group, a methoxy group, an isopropoxy group, an n-propoxy group, an s-butoxy group, a t-butoxy group, a pentoxy group, a hexyloxy group, a cyclopentoxy group, or a cyclohexyloxy group; an aryl group having 5 to 40 atoms; an amino group substituted by an aryl group having 5 to 40 atoms; an ester group including an aryl group having 5 to 40 atoms; an ester group including an alkyl group having 1 to 6 carbon atoms; a cyano group; a nitro group; and a halogen atom such as chlorine, bromine, or iodine.

The luminescent dopant may emit fluorescence, or may emit phosphorescence.

The luminescent dopant that emits phosphorescence preferably contains a metal complex formed of: a metal selected from Ir, Pt, Os, Au, Cu, Re, and Ru; and a ligand. Specific examples of the luminescent dopant that emits phosphorescence include the following compounds as well as iridium(III) bis(2-phenyl quinolyl-N,C2′)acetylacetonate (PQIr) and fac-tris(2-phenylpyridine)iridium (Ir(ppy)₃).

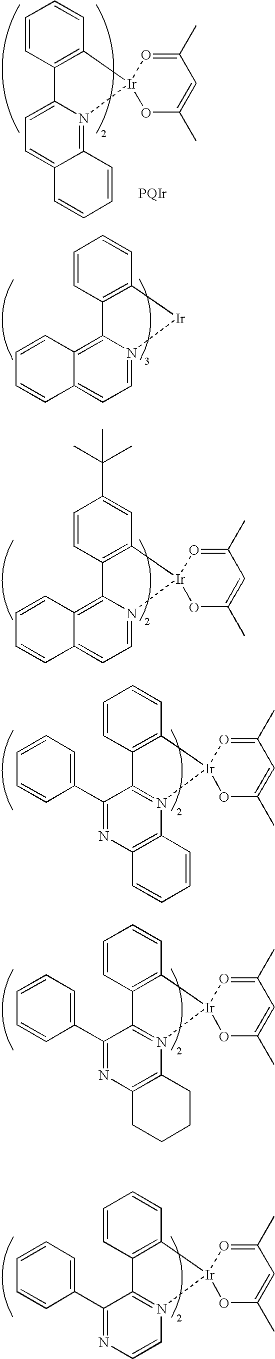

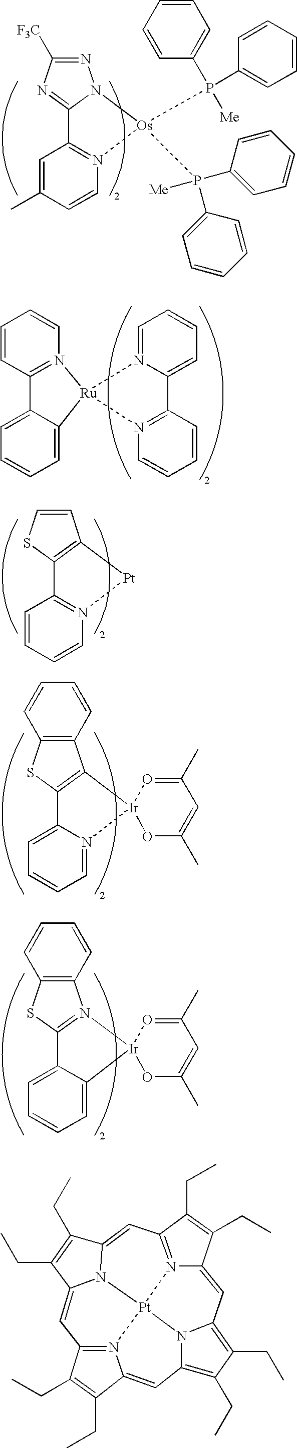

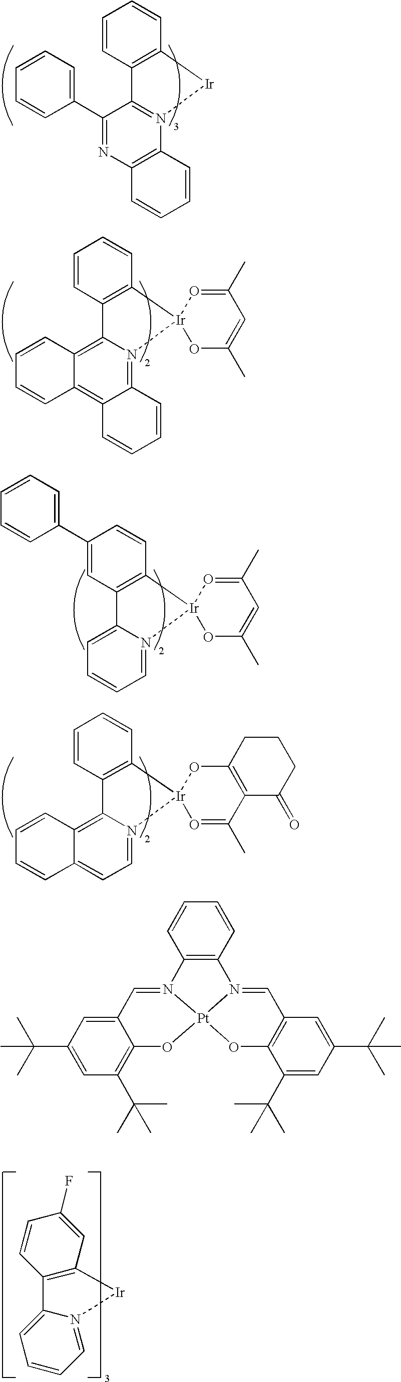

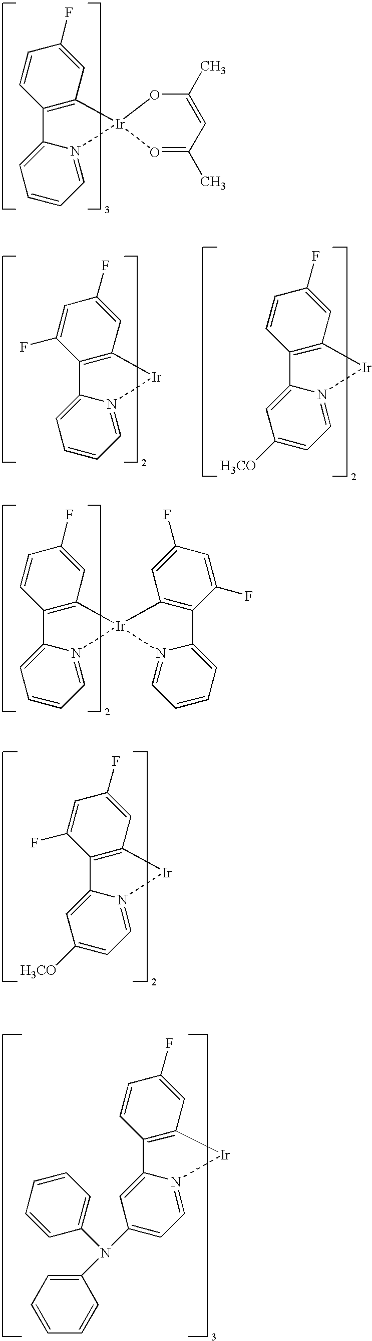

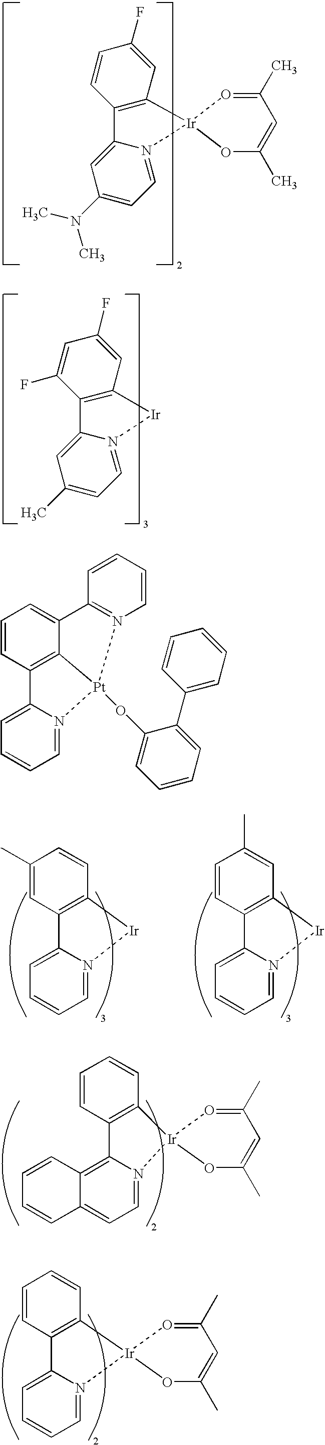

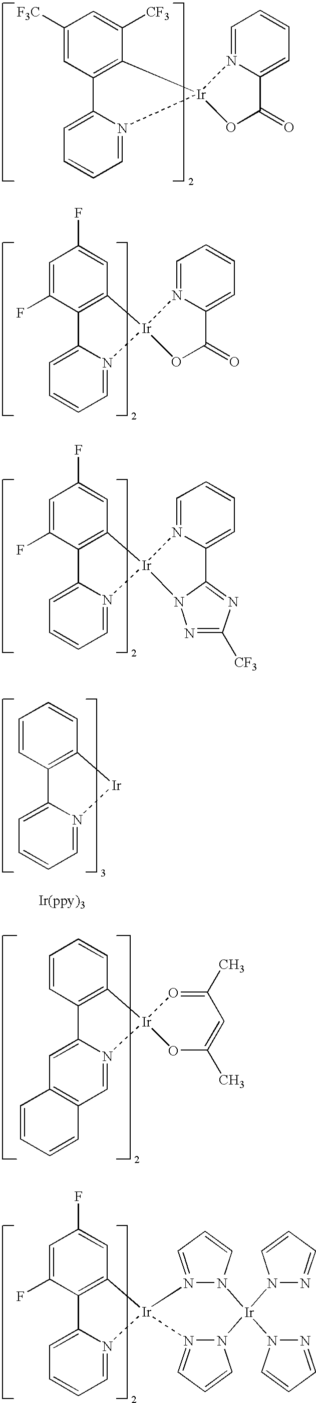

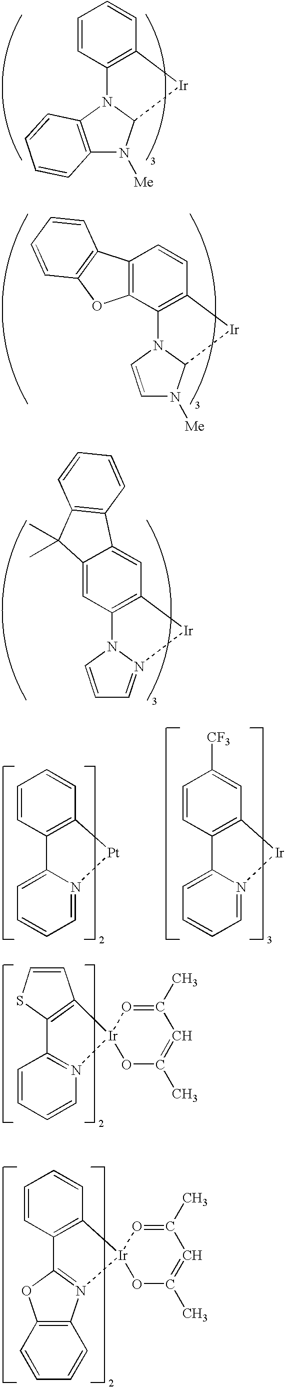

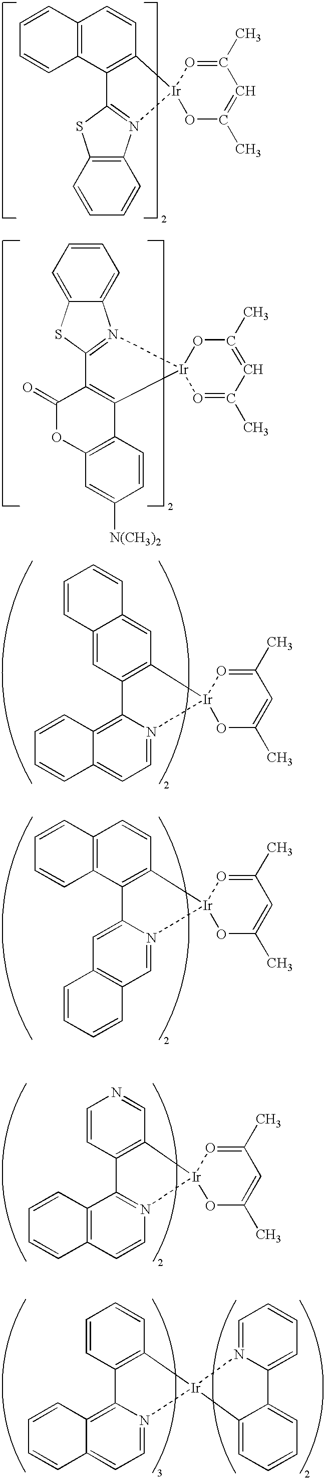

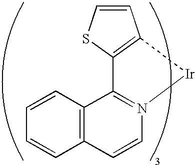

Further, different luminescent dopants may be combined in the luminescent layer. For example, a red luminescent dopant and a blue luminescent dopant may be combined so that white light is emitted. Alternatively, a red luminescent dopant, a blue luminescent dopant and a green luminescent dopant may be combined so that white light is emitted.

Examples of the combination in the luminescent layer include the following combinations:
(1) red luminescent layer/non-doped layer/blue luminescent layer;
(2) blue luminescent layer/non-doped layer/red luminescent layer;
(3) red luminescent layer/non-doped layer/red luminescent layer/non-doped layer/blue luminescent layer;
(4) blue luminescent layer/non-doped layer/blue luminescent layer/non-doped layer/red luminescent layer;
(5) red luminescent layer/non-doped layer/green luminescent layer/non-doped layer/blue luminescent layer; and
(6) blue luminescent layer/non-doped layer/green luminescent layer/non-doped layer/red luminescent layer.

### [Hole Injection/Transport Layer and Electron Injection/Transport Layer]

Examples of the hole injection/transport material for forming the hole injection/transport layer 6 include: a triazole derivative (see, for example, U.S. Pat. No. 3,112,197); an oxadiazole derivative (see, for example, U.S. Pat. No. 3,189,447); an imidazole derivative (see, for example, JP-B-37-16096); a polyarylalkane derivative (see, for example, U.S. Pat. No. 3,615,402, U.S. Pat. No. 3,820,989, U.S. Pat. No. 3,542,544, JP-B-45-555, JP-B-51-10983, JP-A-51-93224, JP-A-55-17105, JP-A-56-4148, JP-A-55-108667, JP-A-55-156953, and JP-A-56-36656); a pyrazoline derivative and a pyrazolone derivative (see, for example, U.S. Pat. No. 3,180,729, U.S. Pat. No. 4,278,746, JP-A-55-88064, JP-A-55-88065, JP-A-49-105537, JP-A-55-51086, JP-A-56-80051, JP-A-56-88141, JP-A-57-45545, JP-A-54-112637, and JP-A-55-74546); a phenylenediamine derivative (see, for example, U.S. Pat. No. 3,615,404, JP-B-51-10105, JP-B-51-10105, JP-B-46-3712, JP-B-47-25336, JP-A-54-53435, JP-A-54-110536, and JP-A-54-119925); an arylamine derivative (see, for example, U.S. Pat. No. 3,567,450, U.S. Pat. No. 3,180,703, U.S. Pat. No. 3,240,597, U.S. Pat. No. 3,658,520, U.S. Pat. No. 4,232,103, U.S. Pat. No. 4,175,961, U.S. Pat. No. 4,012,376, JP-B-49-35702, JP-B-39-27577, JP-A-55-144250, JP-A-56-119132, JP-A-56-22437, and DE 1,110,518); an amino-substituted chalcone derivative (see, for example, U.S. Pat. No. 3,526,501); oxazole derivatives (those disclosed in U.S. Pat. No. 3,257,203); a styrylanthracene derivative (see, for example, JP-A-56-46234); a fluorenone derivative (see, for example, JP-A-54-110837); a hydrazone derivative (see, for example, U.S. Pat. No. 3,717,462, JP-A-54-59143, JP-A-55-52063, JP-A-55-52064, JP-A-55-46760, JP-A-55-85495, JP-A-57-11350, JP-A-57-148749, and JP-A-2-311591); a stilbene derivative (see, for example, JP-A-61-210363, JP-A-61-228451, JP-A-61-14642, JP-A-61-72255, JP-A-62-47646, JP-A-62-36674, JP-A-62-10652, JP-A-62-30255, JP-A-60-93455, JP-A-60-94462, JP-A-60-174749, and JP-A-60-175052); a silazane derivative (U.S. Pat. No. 4,950,950); a polysilane-based copolymer (JP-A-2-204996); an aniline-based copolymer (JP-A-2-282263); and a conductive high molecular weight oligomer (particularly a thiophene oligomer) disclosed in JP-A-1-211399.

In addition to the above-mentioned materials for the hole injection/transport layer, porphyrin compounds (those disclosed in, for example, JP-A-63-295695); an aromatic tertiary amine compound and a styrylamine compound (see, for example, U.S. Pat. No. 4,127,412, JP-A-53-27033, JP-A-54-58445, JP-A-54-149634, JP-A-54-64299, JP-A-55-79450, JP-A-55-144250, JP-A-56-119132, JP-A-61-295558, JP-A-61-98353, and JP-A-63-295695) are preferred, and aromatic tertiary amine compounds are particularly preferred.

Further examples of aromatic tertiary amine compounds include a compound having two fused aromatic rings in the molecule such as 4,4′-bis(N-(1-naphthyl)-N-phenylamino)-biphenyl (hereinafter abbreviated as NPD) as disclosed in U.S. Pat. No. 5,061,569, and a compound in which three triphenylamine units are bonded together in a star-burst shape such as 4,4′,4″-tris(N-(3-methylphenyl)-N-phenylamino)-triphenylamine (hereinafter abbreviated as MTDATA) as disclosed in JP-A-4-308688.

In addition, for example, a hexaazatriphenylene derivative described in Japanese Patent No. 3614405, Japanese Patent No. 3571977, or U.S. Pat. No. 4,780,536 can also be suitably used as a hole-transportable/injectable material.

In addition, an inorganic compound such as p-type Si or p-type SiC can also be used as a hole-transport/injection material.

The electron injection/transport layer 7, which is a layer for aiding an injection of an electron into the luminescent layer, has a large electron mobility. The electron-injection layer is provided for adjusting an energy level (for instance, for alleviating an radical change in energy level). A metal complex of 8-hydroxyquinoline or of a derivative of 8-hydroxyquinoline, an oxadiazole derivative, or a nitrogen-containing heterocyclic derivative is suitable as a material for the electron injection layer or the electron transport layer 7. Specific examples of the above metal complex of 8-hydroxyquinoline or of a derivative of 8-hydroxyquinoline include metal chelate oxynoid compounds each containing a chelate of an oxine (generally 8-quinolinol or 8-hydroxyquinoline) such as tris(8-quinolinol)aluminum. In addition, examples of the oxadiazole derivative include the following derivatives.

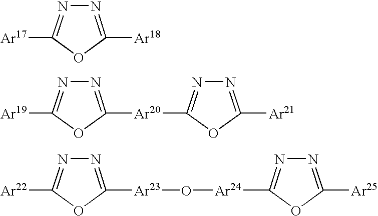

In the above formulae, Ar¹⁷, Ar¹⁸, Ar¹⁹, Ar²¹, Ar²², and Ar²⁵ each represent an aryl group with or without a substituent, and Ar¹⁷ and Ar¹⁸, Ar¹⁹ and Ar²¹, or Ar²² and Ar²⁵ may be identical to or different from each other. Ar²⁰, Ar²³, and Ar²⁴ each represent an arylene group with or without a substituent, and Ar²³ and Ar²⁴ may be identical to or different from each other.

Examples of the aryl group in these general formulae include a phenyl group, a biphenyl group, an anthranyl group, a perylenyl group, and a pyrenyl group. Examples of the arylene group include a phenylene group, a naphthylene group, a biphenylene group, an anthranylene group, a perylenylene group, and a pyrenylene group. Examples of the substituents therefor include alkyl groups having 1 to 10 carbon atoms, alkoxyl groups having 1 to 10 carbon atoms, or a cyano group having 1 to 10 carbon atoms. As an electron transfer compound, compounds which can form thin films are preferable. Further, examples of the electron transfer compounds described above include the following.

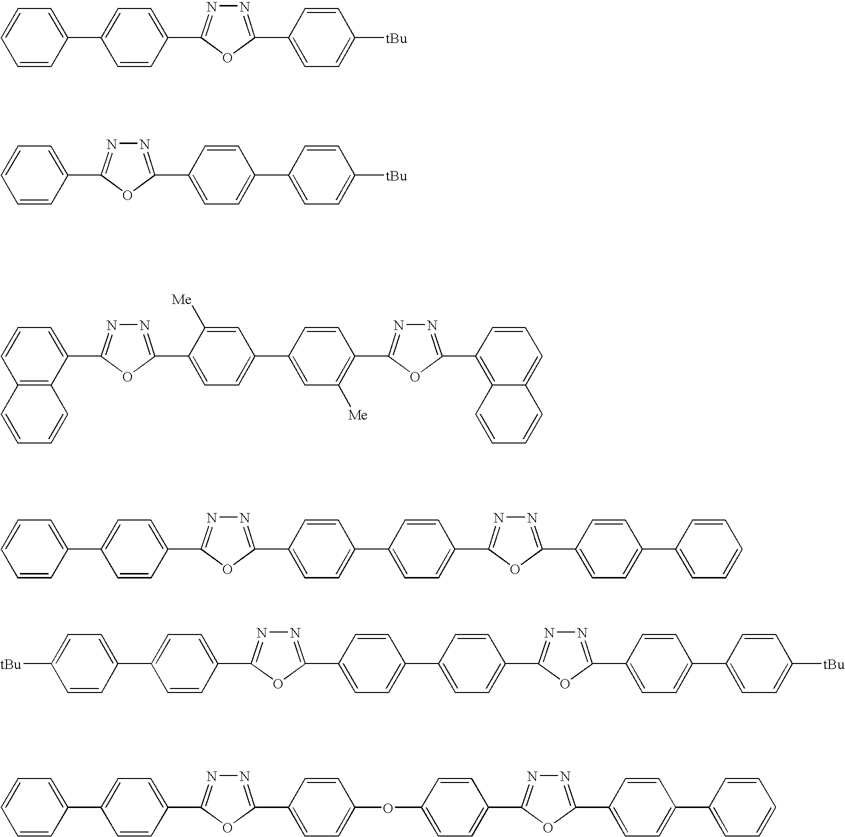

Examples of the nitrogen-containing heterocyclic derivative include nitrogen-containing compounds each of which is not a metal complex but is a nitrogen-containing heterocyclic derivative formed of an organic compound satisfying any one of the following general formulae; and. Examples of the compound include a five- or six-membered ring containing a skeleton shown in a formula (C) and a compound having a structure shown in a formula (D).

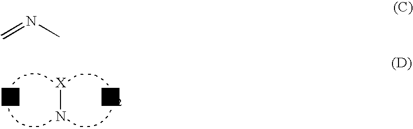

In the above formula (D), X represents a carbon atom or a nitrogen atom, and Z₁ and Z₂ each independently represent an atomic group capable of forming a nitrogen-containing heterocycle.

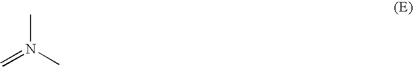

An organic compound having a nitrogen-containing aromatic polycyclic compound formed of a five- or six-membered ring is preferable. Further, in the case of the nitrogen-containing aromatic polycyclic compound having multiple nitrogen atoms, a nitrogen-containing aromatic polycyclic organic compound having a skeleton obtained by combining the above formulae (C) and (D) or the above formulae (C) and (E) is preferable.

A nitrogen-containing group of the nitrogen-containing organic compound is selected from, for example, the nitrogen-containing heterocyclic groups represented by the following general formulae.

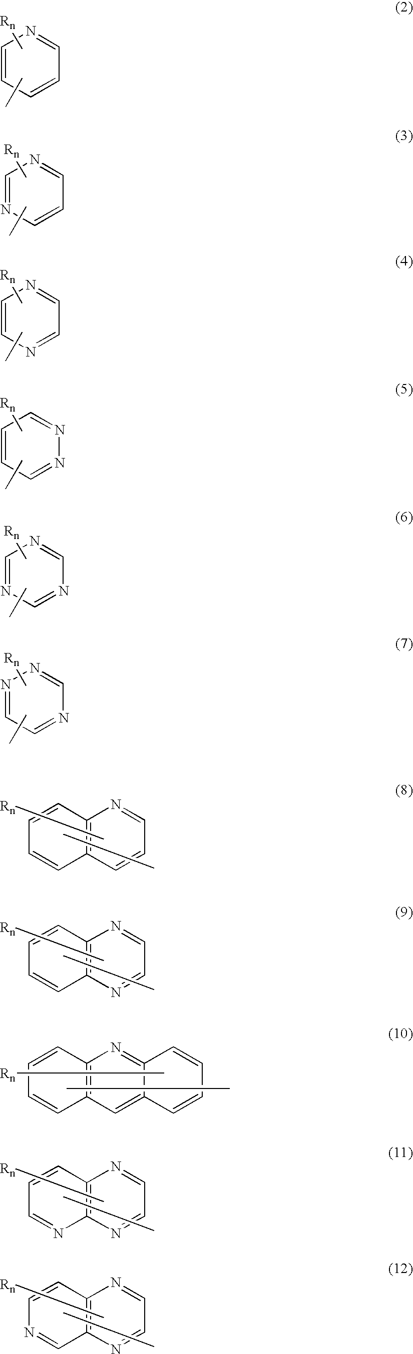

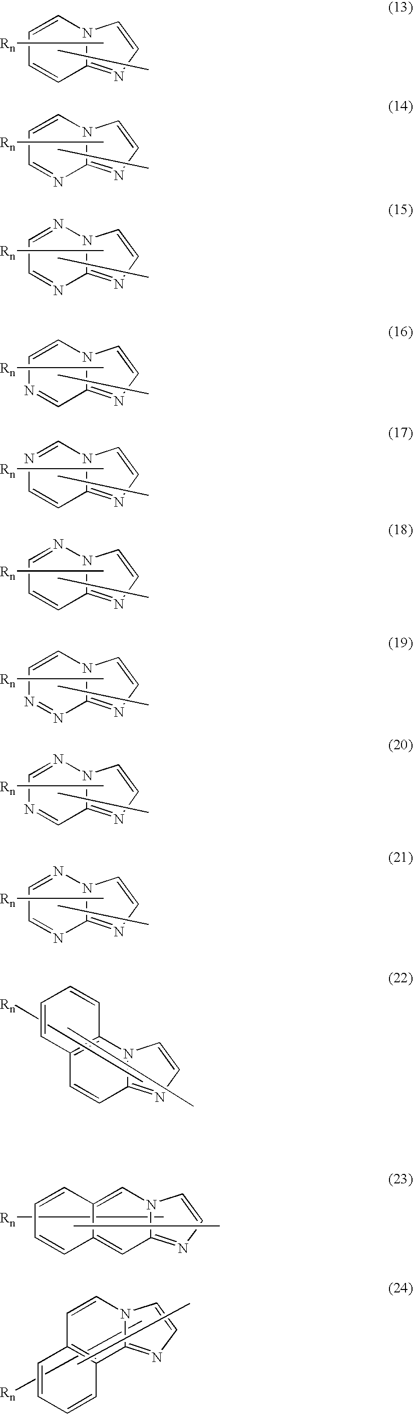

In the above formulae (2) to (24), R represents an aryl group having 6 to 40 carbon atoms, a heteroaryl group having 3 to 40 carbon atoms, and an alkyl group having 1 to 20 carbon atoms, or an alkoxy group having 1 to 20 carbon atoms, n represents an integer in a range of 0 to 5. When n is an integer of 2 or more, multiple R's may be identical to or different from one another.

Further, examples of preferable specific compounds include nitrogen-containing heterocyclic derivatives each represented by the following formula.

HAr-L¹-Ar¹-Ar²

In the above formula, HAr represents a nitrogen-containing heterocyclic ring with 3 to 40 carbon atoms that may have a substituent, L represents a single bond, an arylene group with 6 to 40 carbon atoms that may have a substituent, a heteroarylene group with 3 to 40 carbon atoms that may have a substituent, Ar¹ represents a divalent aromatic hydrocarbon group with 6 to 40 carbon atoms that may have a substituent, and Ar² represents an aryl group with 6 to 40 carbon atoms that may have a substituent, or a heteroaryl group with 3 to 40 carbon atoms that may have a substituent.

HAr is selected from, for example, the following group.

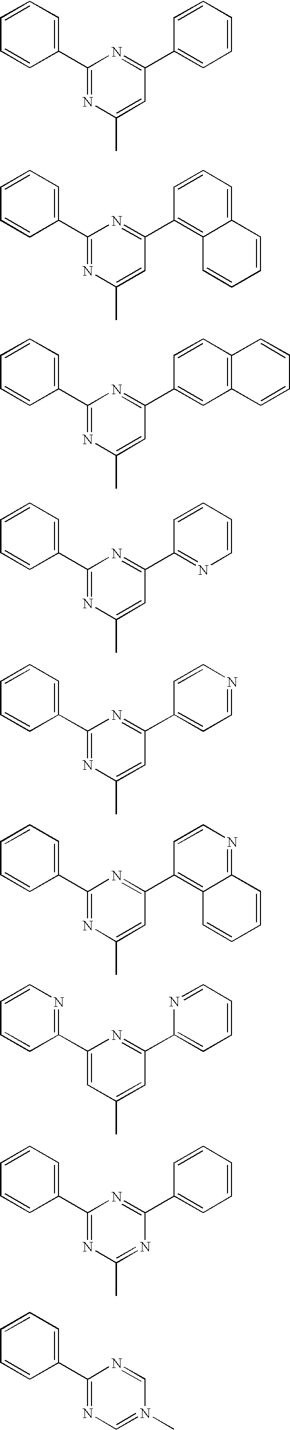

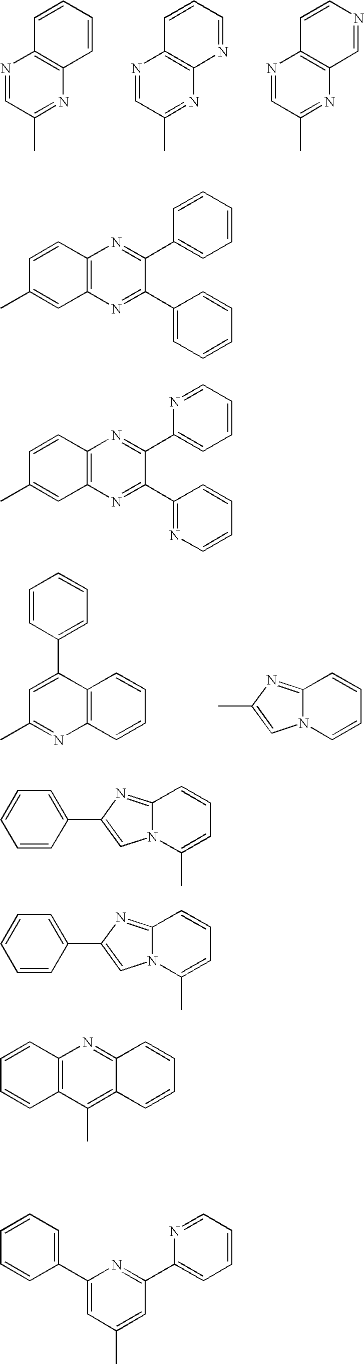

L is selected from, for example, the following group.

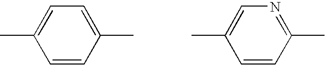

Ar² is selected from, for example, the following group.

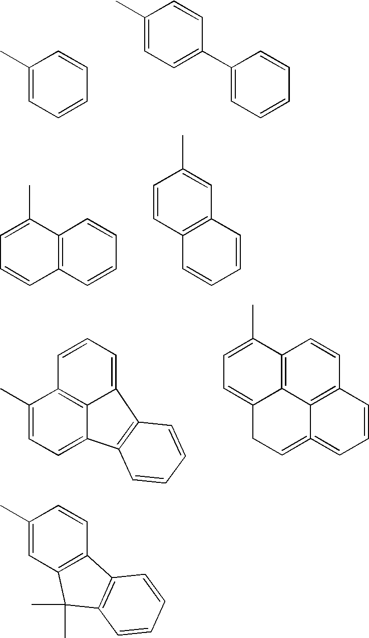

Ar¹ is selected from, for example, the following arylanthranyl groups.

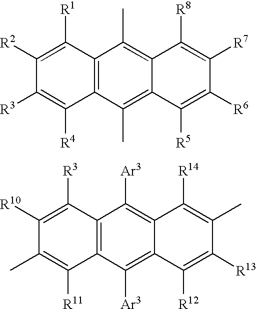

In the above formulae, R¹ to R¹⁴ each independently represent a hydrogen atom, a halogen atom, an alkyl group having 1 to 20 carbon atoms, an alkoxy group having 1 to 20 carbon atoms, an aryloxy group having 6 to 40 carbon atoms, an aryl group with 6 to 40 carbon atoms that may have a substituent, or a heteroaryl group with 3 to 40 carbon atoms that may have a substituent, and Ar³ represents an aryl group with 6 to 40 carbon atoms that may have a substituent, or a heteroaryl group with 3 to 40 carbon atoms that may have a substituent.

In addition, a nitrogen-containing heterocyclic derivative in which R¹ to R⁸ in Ar¹ represented by any one of the above formulae each represent a hydrogen atom may be used.

In addition, the following compound (see JP-A-09-3448) may be also suitably used.

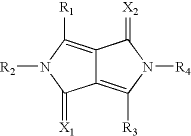

In the above formula, R₁ to R₄ each independently represent a hydrogen atom, a substituted or unsubstituted aliphatic group, a substituted or unsubstituted alicyclic group, a substituted or unsubstituted carbocyclic aromatic ring group, or a substituted or unsubstituted heterocyclic group, and X₁ and X₂ each independently represent an oxygen atom, a sulfur atom, or a dicyanomethylene group.

In addition, the following compound (see JP-A-2000-173774) is also suitably used.

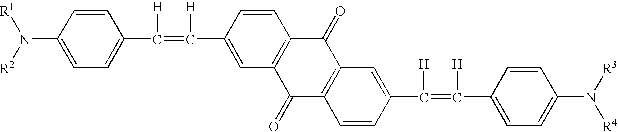

In the above formula, R¹, R², R³, and R⁴ represent groups identical to or different from one another, and each represent an aryl group represented by the following formula.

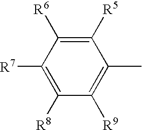

In the above formula, R⁵, R⁶, R⁷, R⁸, and R⁹ represent groups identical to or different from one another. All of R⁵ to R⁹ may be hydrogen atoms, or at least one of R⁵ to R⁹ may be a saturated or unsaturated alkoxyl, alkyl, amino, or alkylamino group.

Further, a high polymer compound containing the nitrogen-containing heterocyclic group or nitrogen-containing heterocyclic derivative may be used.

A thickness of the electron injection layer or the electron transport layer, which is not particularly limited, is preferably 1 to 100 nm.

### EXAMPLES

Next, the present invention will be described in more detail with reference to examples and comparative examples. However, the present invention is by no means limited to what is described in the examples.

### Example 1

A glass substrate with an ITO transparent electrode (size: 25 mm by 75 mm by 1.1 mm, manufactured by GEOMATEC Co., Ltd.) was subjected to ultrasonic cleaning in isopropyl alcohol for 5 minutes. After that, the substrate was subjected to UV/ozone cleaning for 30 minutes.

The cleaned glass substrate provided with a transparent electrode line was mounted in a substrate holder of a vacuum deposition apparatus. First, N,N′-bis[4-(N,N-diphenylamino)phenyl-1-yl]-N,N′-diphenyl-4,4′-benzidine was deposited by a thickness of 60 nm onto a surface where the transparent electrode line was formed, thereby forming a hole-injection layer. After that, N,N′-bis[4′-{N-(naphthyl-1-yl)-N-phenyl}aminobiphenyl-4-yl]-N-phenylamine was deposited by a thickness of 10 m onto the hole injection layer to form a hole-transport layer.

Further, a luminescent layer in which a compound RH1 served as a host while a compound RD1 served as a luminescent dopant was formed.

Specifically, the compound RD1 serving as the luminescent dopant and the compound RH1 serving as the host were placed in different deposition sources of the deposition apparatus. Then, both boats were heated while a shutter provided on a side adjacent to the compound RD1 was suitably switched to be opened or closed, whereby two doped regions and one non-doped region were laminated such that the non-doped region was interposed between the two doped regions.

At this time, the doped regions were adjusted to be 5 nm thick while the non-doped region was adjusted to 30 nm thick by setting time period for which the shutter was opened or closed. The entire luminescent layer was 40 nm thick.

In addition, the concentration of the luminescent dopant in each of the doped regions was set to be 2 mass %.

Next, a compound ET was formed into a film of 30 nm thick on the luminescent layer by resistance heating deposition. The ET film was to function as an electron transport layer.

After that, LiF was formed into a film of 1 nm thick. Metal Al was deposited by a thickness of 150 nm onto the LiF film to form a metal cathode, thereby forming an organic electroluminescence light-emitting device.

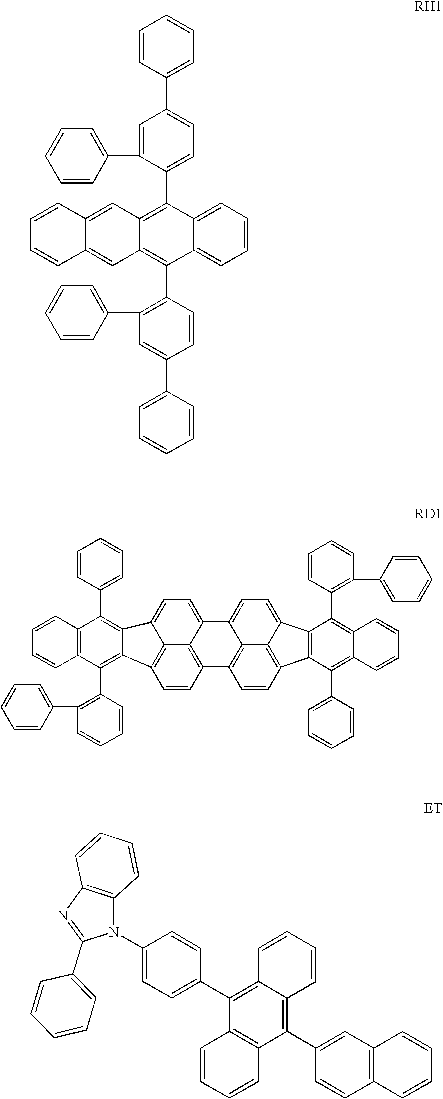

### Examples 2 to 27 and Comparative Examples 1 to 11

Organic electroluminescence devices were each produced in the same manner as in Example 1 except that the arrangement of a luminescent layer was changed as shown in each of Tables 1 and 2 below.

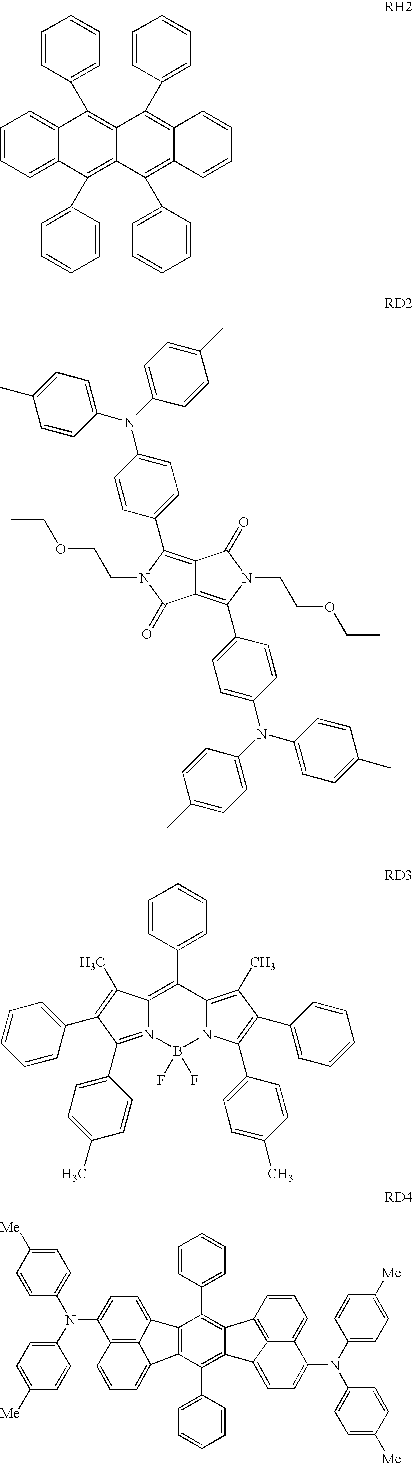

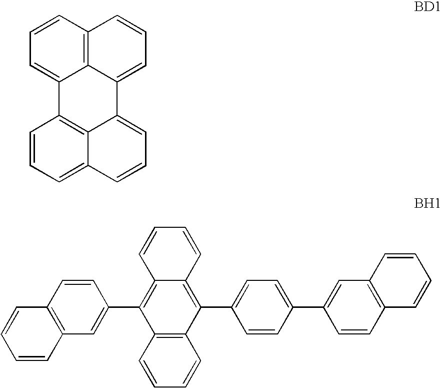

TABLE 1

| | Arrangement of luminescent | Number of | Number of |
|---|---|---|---|
| | layer (d: doped region, | doped | non-doped |
| | n: non-doped region) | regions | regions |
| Example 1 | d/n/d | 2 | 1 |
| Example 2 | d/n/d | 2 | 1 |
| Example 3 | d/n/d | 2 | 1 |
| Example 4 | d/n/d/n/d/n/d/n | 4 | 4 |
| Example 5 | d/n/d/n/d | 3 | 2 |
| Example 6 | d/n/d/n/d | 3 | 2 |
| Example 7 | d/n/d/n/d/n/d | 4 | 3 |
| Example 8 | d/n/d/n/d/n/d/n/d | 5 | 4 |
| Example 9 | d/n/d/. . . /d/n/d | 10 | 9 |
| Example 10 | n/d/n/d/n/d/n | 3 | 4 |
| Example 11 | n/d/n/d/n/d/n/d/n | 4 | 5 |
| Example 12 | n/d/n/d/n/d/n/d/n/d/n/d/n | 6 | 7 |
| Example 13 | n/d/n/ . . . /n/d/n | 13 | 14 |
| Example 14 | n/d/n/ . . . /n/d/n | 16 | 17 |
| Example 15 | n/d/n/ . . . /n/d/n | 22 | 23 |
| Example 16 | n/d/n/ . . . /n/d/n | 33 | 34 |
| Example 17 | n/d/n/. . . /n/d/n | 66 | 67 |
| Example 18 | d/n/d/n/d | 3 | 2 |
| Example 19 | d/n/d/n/d/n/d | 4 | 3 |
| Example 20 | d/n/d/n/d/n/d/n/d | 5 | 4 |
| Example 21 | d/n/d/. . . /d/n/d | 10 | 9 |
| Example 22 | d/n/d/. . . /d/n/d | 10 | 9 |
| Example 23 | d/n/d/. . . /d/n/d | 10 | 9 |
| Example 24 | d/n/d/. . . /d/n/d | 10 | 9 |
| Example 25 | d/n/d/. . . /d/n/d | 10 | 9 |
| Example 26 | d/n/d/. . . /d/n/d | 10 | 9 |
| Example 27 | d/n/d/ . . . /d/n/d | 10 | 9 |
| Comparative | d | 1 | 0 |
| Example 1 | | | |
| Comparative | d | 1 | 0 |
| Example 2 | | | |
| Comparative | d | 1 | 0 |
| Example 3 | | | |
| Comparative | d/n | 1 | 1 |
| Example 4 | | | |
| Comparative | n/d | 1 | 1 |
| Example 5 | | | |
| Comparative | d | 1 | 0 |
| Example 6 | | | |
| Comparative | d | 1 | 0 |
| Example 7 | | | |
| Comparative | d | 1 | 0 |
| Example 8 | | | |
| Comparative | d | 1 | 0 |
| Example 9 | | | |
| Comparative | d | 1 | 0 |
| Example 10 | | | |

TABLE 2

| | | | | | | Concentration of | |
|---|---|---|---|---|---|---|---|
| | | Host | | | | luminescent | |
| | Host | material | | | | dopant (mass %) | |
| | material for | for | Luminescent | Thickness (nm) | | | Entire |
| | doped | non-doped | dopant | Doped | Non-doped | Doped | luminescent |
| | region | region | material | region | region | region | layer |
| Example 1 | RH1 | RH1 | RD1 | 5 | 30 | 2 | 0.5 |
| Example 2 | RH1 | RH1 | RD1 | 5 | 40 | 2 | 0.4 |
| Example 3 | RH1 | RH1 | RD1 | 5 | 50 | 2 | 0.33 |
| Example 4 | RH1 | RH1 | RD1 | 5 | 5 | 2 | 1 |
| Example 5 | RH1 | RH1 | RD1 | 3.3 | 15 | 2 | 0.5 |
| Example 6 | RH1 | RH1 | RD1 | 0.7 | 19 | 10 | 0.52 |
| Example 7 | RH1 | RH1 | RD1 | 2.5 | 10 | 2 | 0.5 |
| Example 8 | RH1 | RH1 | RD1 | 2 | 7.5 | 2 | 0.5 |
| Example 9 | RH1 | RH1 | RD1 | 1 | 3.3 | 2 | 0.5 |
| Example 10 | RH1 | RH1 | RD1 | 3 | 9 | 2 | 0.4 |
| Example 11 | RH1 | RH1 | RD1 | 2.25 | 6.75 | 2 | 0.42 |
| Example 12 | RH1 | RH1 | RD1 | 1.5 | 4.5 | 2 | 0.44 |
| Example 13 | RH1 | RH1 | RD1 | 0.75 | 2.25 | 2 | 0.47 |
| Example 14 | RH1 | RH1 | RD1 | 0.6 | 1.8 | 2 | 0.48 |
| Example 15 | RH1 | RH1 | RD1 | 0.45 | 1.35 | 2 | 0.48 |
| Example 16 | RH1 | RH1 | RD1 | 0.3 | 0.9 | 2 | 0.49 |
| Example 17 | RH1 | RH1 | RD1 | 0.15 | 0.45 | 2 | 0.49 |
| Example 18 | RH1 | RH1 | RD1 | 3.3 | 15 | 0.5 | 0.12 |
| Example 19 | RH1 | RH1 | RD1 | 2.5 | 10 | 0.5 | 0.13 |
| Example 20 | RH1 | RH1 | RD1 | 2 | 7.5 | 0.5 | 0.13 |
| Example 21 | RH1 | RH1 | RD1 | 1 | 3.3 | 0.5 | 0.13 |
| Example 22 | RH2 | RH2 | RD1 | 1 | 3.3 | 2 | 0.5 |
| Example 23 | RH1 | RH2 | RD1 | 1 | 3.3 | 2 | 0.5 |
| Example 24 | RH2 | RH1 | RD1 | 1 | 3.3 | 2 | 0.5 |
| Example 25 | RH1 | RH1 | RD2 | 1 | 3.3 | 4 | 1 |
| Example 26 | RH1 | RH1 | RD3 | 1 | 3.3 | 4 | 1 |
| Example 27 | BH1 | BH1 | BD1 | 1 | 3.3 | 20 | 5 |
| Comparative | RH1 | — | RD1 | 40 | — | 0.5 | 0.5 |
| Example 1 | | | | | | | |
| Comparative | RH1 | — | RD1 | 40 | — | 2 | 2 |
| Example 2 | | | | | | | |
| Comparative | RH1 | — | RD1 | 40 | — | 10 | 10 |
| Example 3 | | | | | | | |
| Comparative | RH1 | RH1 | RD1 | 10 | 30 | 2 | 0.5 |
| Example 4 | | | | | | | |
| Comparative | RH1 | RH1 | RD1 | 10 | 30 | 2 | 0.5 |
| Example 5 | | | | | | | |
| Comparative | RH2 | — | RD1 | 40 | — | 2 | 2 |
| Example 6 | | | | | | | |
| Comparative | RH1 | — | RD2 | 40 | — | 1 | 1 |
| Example 7 | | | | | | | |
| Comparative | RH1 | — | RD2 | 40 | — | 2 | 2 |
| Example 8 | | | | | | | |
| Comparative | RH1 | — | RD3 | 40 | — | 2 | 2 |
| Example 9 | | | | | | | |
| Comparative | BH1 | — | BD1 | 40 | — | 10 | 10 |
| Example 10 | | | | | | | |

### [Evaluation of Organic Electroluminescence Device]

A direct current of 10 mA/cm² was flowed in each of the organic electroluminescence devices produced as described above so that the device emitted light, and luminance (L) of each of the devices was measured. Current efficiency (L/J) was obtained on the basis of the measured luminance.

Table 3 below shows the results.

TABLE 3

| | Current efficiency L/J |
|---|---|
| | (cd/A) |
| Example 1 | 9.7 |
| Example 2 | 8.8 |
| Example 3 | 8.6 |
| Example 4 | 9.6 |
| Example 5 | 10.3 |
| Example 6 | 9.0 |
| Example 7 | 10.9 |
| Example 8 | 11.0 |
| Example 9 | 11.5 |
| Example 10 | 9.1 |
| Example 11 | 9.7 |
| Example 12 | 10.6 |
| Example 13 | 11.2 |
| Example 14 | 11.6 |
| Example 15 | 11.3 |
| Example 16 | 11.8 |
| Example 17 | 9.5 |
| Example 18 | 12.4 |
| Example 19 | 12.4 |
| Example 20 | 12.5 |
| Example 21 | 12.6 |
| Example 22 | 10.5 |
| Example 23 | 11.0 |
| Example 24 | 10.8 |
| Example 25 | 6.75 |
| Example 26 | 7.11 |
| Example 27 | 6.95 |
| Comparative Example 1 | 11.4 |
| Comparative Example 2 | 8.5 |
| Comparative Example 3 | 2.6 |
| Comparative Example 4 | 7.1 |
| Comparative Example 5 | 7.6 |
| Comparative Example 6 | 8.3 |
| Comparative Example 7 | 6.23 |
| Comparative Example 8 | 4.35 |
| Comparative Example 9 | 5.23 |
| Comparative Example 10 | 3.45 |

As is obvious from Table 3, each of the organic electroluminescence devices of Examples 1 to 27 as arranged according to the present invention emitted red light or blue light with high efficiency as compared to: the organic electroluminescence devices of Comparative Examples 1 to 3 and 6 to 10 in which no non-doped region was provided; the organic electroluminescence devices of Comparative Examples 4 and 5 in which only one doped region was provided; and the organic electroluminescence device of Comparative Example 11 in which the non-doped region was excessively thick.

In Comparative Example 1, the concentration of the luminescent dopant in each doped region was 0.5 mass %, and the concentration of the luminescent dopant in the entire luminescent layer was also 0.5 mass %.

In contrast, in each of Examples 18 to 21, although the concentration of the luminescent dopant in each doped region was 0.5 mass %, the concentration of the luminescent dopant in the entire luminescent layer was lowered due to the present of the non-doped regions.

Consequently, in each of Examples 18 to 21, concentration quenching was hardly caused, whereby the organic electroluminescence devices emitted light with high efficiency as compared to Comparative Example 1.

In Comparative Example 2, the concentration of the luminescent dopant in each doped region was 2 mass %, and the concentration of the luminescent dopant in the entire luminescent layer was also 2 mass % because no non-doped region was provided.

In contrast, in each of Examples 1 to 5 and 7 to 17, the concentration of the luminescent dopant in each doped region was 2 mass %, but the concentration of the luminescent dopant in the entire luminescent layer was lowered due to the presence of the non-doped region(s).

Consequently, in each of Examples 1 to 5 and 7 to 17, concentration quenching was hardly caused, whereby the organic electroluminescence device emitted light with high efficiency as compared to Comparative Example 2.

In Comparative Example 3, the concentration of the luminescent dopant in each doped region was 10 mass %, and the concentration of the luminescent dopant in the entire luminescent layer was also 10 mass % because no non-doped region was provided.

In contrast, in Example 6, although the concentration of the luminescent dopant in each doped region was 10 mass %, the concentration of the luminescent dopant in the entire luminescent layer was lowered due to the presence of the non-doped regions.

Consequently, in Example 6, concentration quenching was hardly caused, whereby the organic electroluminescence device emitted light with high efficiency as compared to Comparative Example 2.

The organic electroluminescence devices of Comparative Examples 4 and 5 each had only one doped region and exhibited lower luminous efficiency than that of the organic electroluminescence device of Example 1 having two doped regions.

It can be understood from the above that two or more doped regions need to be laminated for light emission of high efficiency.

The host of each of the doped regions and the non-doped regions was changed to the compound RH2 in Example 22, and the host of each of the doped regions was changed to the compound RH2 in Example 24. The organic electroluminescence devices of the above examples each also exhibited higher luminous efficiency than the organic electroluminescence device of Comparative Example 6 in which the compound RH2 served as a host while no non-doped region was provided.

In addition, the organic electroluminescence device of Example 23 in which the host of each of the non-doped regions was changed to the compound RH2 exhibited higher luminous efficiency than the organic electroluminescence devices of Comparative Examples 1 and 6.

The luminescent dopant was changed to the compound RD2 in Example 25. The organic electroluminescence device of the example also exhibited higher luminous efficiency than the organic electroluminescence devices of Comparative Examples 7 and 8 whose luminescent dopant was similarly changed to the compound RD2.

The luminescent dopant was changed to the compound RD3 in Example 26. The organic electroluminescence device of the example also exhibited higher luminous efficiency than the organic electroluminescence device of Comparative Example 9 whose luminescent dopant was similarly changed to the compound RD3.

In Example 27, The host of each of the doped regions and the non-doped regions was changed to the compound BH1 while the luminescent dopant was changed to the compound BD1. The organic electroluminescence device of the example also exhibited higher luminous efficiency than the organic electroluminescence device of Comparative Example 10 in which similar changes were made.

### Example 28

An organic electroluminescence device was produced in the same manner as in Example 27 except that the following changes were made: the compound BD1 was used as a luminescent dopant in each of the three doped regions out of the doped regions of Example 27 counted from the anode side, and the concentration of the luminescent dopant in each of the three doped regions was set to be 20 mass %; and the compound RD4 was used as a luminescent dopant in each of the seven other doped regions, and the concentration of the luminescent dopant in each of the seven doped regions was set to be 10 mass %.

An average concentration of the compound BD1 in the entire luminescent layer was 1.5 mass % while an average concentration of the compound RD4 in the entire luminescent layer was 1.8 mass %.

A direct current of 10 mA/cm² was flowed in the organic electroluminescence device so that the device emitted light. At this time, the device exhibited a current efficiency (L/J) of 9.2 cd/A and emitted white light.

### Comparative Example 11

An organic electroluminescence device was produced in the same manner as in Comparative Example 10 except that the arrangement was changed such that a luminescent layer was divided into two layers. Specifically, a 12-nm-thick first layer containing 20 mass % of the compound BD1 as a luminescent dopant was provided on an anode side while a 28-nm-thick second layer containing 10 mass % of the compound RD4 as a luminescent dopant was provided on a cathode side.

A direct current of 10 mA/cm² was flowed in the organic electroluminescence device such that the device emitted light. At this time, the device exhibited a current efficiency (L/J) of 2.2 cd/A, a value decreased owing to concentration quenching. The organic electroluminescence device of Comparative Example 11 showed much lower efficiency than the organic electroluminescence device of Example 28.

The Priority Application Number JP2007-203540 upon which this patent application is based is hereby incorporated by reference.

What is claimed is:

1. An organic electroluminescence device, comprising:
an anode;
a cathode; and
a luminescent layer provided between the anode and the cathode, wherein the luminescent layer includes:
two or more doped regions each containing a luminescent dopant; and
at least one non-doped region in which the luminescent dopant is not contained.

2. The organic electroluminescence device according to claim 1, wherein the luminescent dopant includes an substituted or unsubstituted aromatic compound having a fused aromatic ring in which 3 to 15 rings are included.

3. The organic electroluminescence device according to claim 1, wherein the at least one non-doped region is thicker than each of the doped regions.

4. The organic electroluminescence device according to claim 3, wherein the at least one non-doped region has a thickness of 0.1 nm or more to 50 nm or less.

5. The organic electroluminescence device according to claim 1, wherein an affinity level Af_{H} of a host included in each of the doped regions and an affinity level Af_{D} of the luminescent dopant contained in each of the doped regions satisfy the following formula:
Af_{D}−Af_{H}>0.1 eV.

6. The organic electroluminescence device according to claim 1, wherein an ionization potential Ip_{H} of a host included in each of the doped regions and an ionization potential Ip_{D} of the luminescent dopant contained in each of the doped regions satisfy the following formula:
Ip_{H}−Ip_{D}≧0.1 eV.

7. The organic electroluminescence device according to claim 1, wherein a host included in each of the doped regions and a host included in the at least one non-doped region have the same composition.

8. The organic electroluminescence device according to claim 1, wherein the luminescent dopants contained in the doped regions shows different luminescent colors.

9. The organic electroluminescence device according to claim 1, wherein the luminescent dopant contains a red luminescent dopant that emits red light.

10. The organic electroluminescence device according to claim 1, wherein the luminescent dopant contained in each of the doped regions is a compound having one of a fluoranthene skeleton and a perylene skeleton.

11. The organic electroluminescence device according to claim 10, wherein the compound having one of a fluoranthene skeleton and a perylene skeleton is an indenoperylene derivative represented by one of the following formulae (1) and (2). 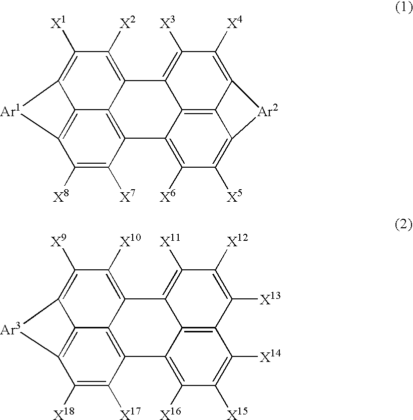
(where: Ar¹, Ar² and Ar³ each represent a substituted or unsubstituted aromatic ring group, or a substituted or unsubstituted aromatic heterocyclic group; X¹ to X¹⁸ each represent a hydrogen atom, a halogen atom, an alkyl group, an alkoxy group, an alkylthio group, an alkenyl group, an alkenyloxy group, an alkenylthio group, an aromatic ring-containing alkyl group, an aromatic ring-containing alkyloxy group, an aromatic ring-containing alkylthio group, an aromatic ring group, an aromatic heterocyclic group, an aromatic ring oxy group, an aromatic ring thio group, an aromatic ring alkenyl group, an alkenyl aromatic ring group, an amino group, a carbazolyl group, a cyano group, a hydroxyl group, —COOR¹′ (R¹′ represents a hydrogen atom, an alkyl group, an alkenyl group, an aromatic ring-containing alkyl group, or an aromatic ring group), —COR²′(R²′ represents a hydrogen atom, an alkyl group, an alkenyl group, an aromatic ring-containing alkyl group, an aromatic ring group, or an amino group), or —OCOR³′(R³′ represents an alkyl group, an alkenyl group, an aromatic ring-containing alkyl group, or an aromatic ring group); and adjacent groups of X¹ to X¹⁸ may be bonded to one another to form a ring, or may form a ring together with a substituted carbon atom.)

12. The organic electroluminescence device according to claim 11, wherein the indenoperylene derivative is a dibenzotetraphenylperiflanthene derivative.

13. The organic electroluminescence device according to claim 10, wherein the luminescent dopant, instead of being the compound having one of a fluoranthene skeleton and a perylene skeleton, is one of a compound having a pyrromethene skeleton represented by the following formula (3) and a metal complex of the compound. 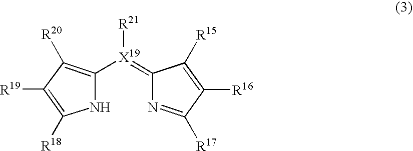
(where: at least one of R¹⁵ to R²¹ contains an aromatic ring or forms a fused ring together with an adjacent substituent; the remainder of R¹⁵ to R²¹ are each independently selected from a group consisting of a hydrogen atom, an alkyl group, a cycloalkyl group, an aralkyl group, an alkenyl group, a cycloalkenyl group, an alkynyl group, a hydroxyl group, a mercapto group, an alkoxy group, an alkylthio group, an arylether group, an arylthioether group, an aryl group, a heterocyclic group, a halogen atom, a haloalkane, a haloalkene, a haloalkyne, a cyano group, an aldehyde group, a carbonyl group, a carboxyl group, an ester group, a carbamoyl group, an amino group, a nitro group, a silyl group, a siloxanyl group, and a fused ring or aliphatic ring formed together with an adjacent substituent (each of the groups has 1 to 20 carbon atoms), X¹⁹ representing a carbon atom or a nitrogen atom, R²¹ not being present when X¹⁹ represents a nitrogen atom; and a metal of the metal complex includes at least one metal selected from a group consisting of boron, beryllium, magnesium, chromium, iron, cobalt, nickel, copper, zinc, and platinum.)

14. The organic electroluminescence device according to claim 10, wherein the luminescent dopant, instead of being the compound having one of a fluoranthene skeleton and a perylene skeleton, is a diketopyrrolopyrrole derivative represented by the following formula (4). 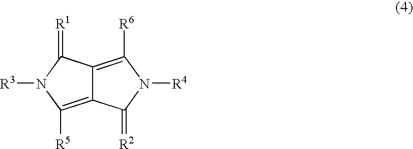
(where: R¹ and R² each independently represent an oxygen atom or a nitrogen atom substituted by a cyano group; R³ and R⁴ each independently represent a hydrogen atom, a halogen atom, an alkyl group, an alkenyl group, an aryl group, a heterocyclic group, or COOR⁷ where R⁷ represents an alkyl group, an alkenyl group, an aryl group, or a heterocyclic group; and R⁵ and R⁶ each independently represent an aryl group or a heterocyclic group.)

15. The organic electroluminescence device according to claim 1, wherein a host contained in at least one of the doped regions and the at least one non-doped region includes a compound having a fused aromatic ring group having 3 or more carbon rings, the fused aromatic ring group being substituted or unsubstituted.

16. The organic electroluminescence device according to claim 1, wherein a host contained in at least one of the doped regions and the at least one non-doped region includes a compound having a fused aromatic ring group having 4 or more carbon rings, the fused aromatic ring group being substituted or unsubstituted.

17. The organic electroluminescence device according to claim 16, wherein the host contained in at least one of the doped regions and the at least one non-doped region includes a naphthacene derivative represented by the following formula (5). 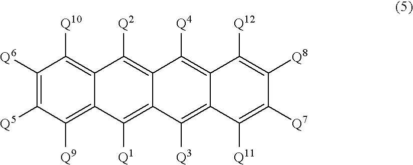
(where Q¹ to Q¹² each independently represent a hydrogen atom, a substituted or unsubstituted alkyl group having 1 to 20 carbon atoms, a substituted or unsubstituted aryl group having 6 to 20 carbon atoms, an amino group, a substituted or unsubstituted alkoxy group having 1 to 20 carbon atoms, a substituted or unsubstituted alkylthio group having 1 to 20 carbon atoms, a substituted or unsubstituted aryloxy group having 6 to 20 carbon atoms, a substituted or unsubstituted arylthio group having 6 to 20 carbon atoms, a substituted or unsubstituted alkenyl group having 2 to 20 carbon atoms, a substituted or unsubstituted aralkyl group having 7 to 20 carbon atoms, or a substituted or unsubstituted heterocyclic group having 5 to 20 atoms, and Q¹ to Q¹² may be identical to or different from one another.)

18. The organic electroluminescence device according to claim 17, wherein at least one of Q¹, Q², Q³ and Q⁴ in the naphthacene derivative represented by the formula (5) represents an aryl group.

19. The organic electroluminescence device according to claim 17, wherein the naphthacene derivative represented by the formula (5) is represented by the following formula (6). 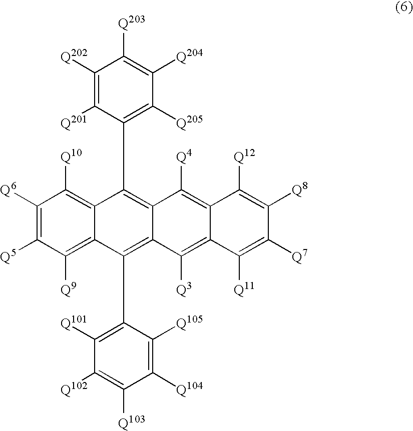
(where Q³ to Q¹², Q¹⁰¹ to Q¹⁰⁵, and Q²⁰¹ to Q²⁰⁵ each independently represent a hydrogen atom, a substituted or unsubstituted alkyl group having 1 to 20 carbon atoms, a substituted or unsubstituted aryl group having 6 to 20 carbon atoms, an amino group, a substituted or unsubstituted alkoxy group having 1 to 20 carbon atoms, a substituted or unsubstituted alkylthio group having 1 to 20 carbon atoms, a substituted or unsubstituted aryloxy group having 6 to 20 carbon atoms, a substituted or unsubstituted arylthio group having 6 to 20 carbon atoms, a substituted or unsubstituted alkenyl group having 2 to 20 carbon atoms, a substituted or unsubstituted aralkyl group having 7 to 20 carbon atoms, or a substituted or unsubstituted heterocyclic group having 5 to 20 atoms, and Q³ to Q¹², Q¹⁰¹ to Q¹⁰⁵, and Q²⁰¹ to Q²⁰⁵ may be identical to or different from one another.)

20. The organic electroluminescence device according to claim 19, wherein at least one of Q¹⁰¹, Q¹⁰⁵, Q²⁰¹ and Q²⁰⁵ in the naphthacene derivative represented by the formula (6) represents an alkyl group, an aryl group, an amino group, an alkoxy group, an aryloxy group, an alkylthio group, an arylthio group, an alkenyl group, an aralkyl group, or a heterocyclic group, and Q¹⁰¹, Q¹⁰⁵, Q²⁰¹ and Q²⁰⁵ are identical to or different from one another.

21. The organic electroluminescence device according to claim 15, wherein the host contained in at least one of the doped regions and the at least one non-doped region includes a compound represented by the following formula (7).
X—(Y)ₙ (7)
(where:
X represents a fused aromatic ring group having 3 or more carbon rings;
Y represents a group selected from a group consisting of a substituted or unsubstituted aryl group, a substituted or unsubstituted diarylamino group, a substituted or unsubstituted arylalkyl group, and a substituted or unsubstituted alkyl group; and
n represents an integer in a range of 1 to 6, and when n represents 2 or more, Ys may be identical to or different from each other.)

22. The organic electroluminescence device according to claim 21, wherein the compound represented by the formula (7) is an anthracene derivative represented by the following formula (8). 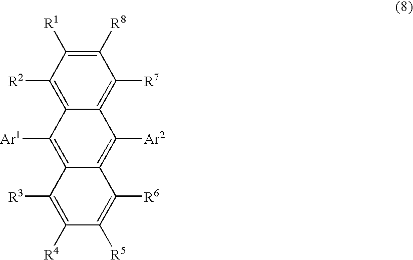
(where: Ar¹ and Ar² each independently represent a group derived from a substituted or unsubstituted aromatic ring having 6 to 20 carbon atoms, the aromatic ring being substituted by at least one substituent or unsubstituted, the at least one substituent being selected from a group consisting of a substituted or unsubstituted aryl group having 6 to 50 carbon atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, and a hydroxy group, two or more substituents being identical to or different from each other when the aromatic ring is substituted by the two or more substituents, adjacent substituents being bonded to each other to form a saturated or unsaturated cyclic structure or not being bonded to each other; and
R¹ to R⁸ are each selected from a group consisting of a hydrogen atom, a substituted or unsubstituted aryl group having 6 to 50 carbon atoms, a substituted or unsubstituted heteroaryl group having 5 to 50 atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms, a substituted or unsubstituted arylthio group having 5 to 50 atoms, a substituted or unsubstituted alkoxycarbonyl group having 1 to 50 carbon atoms, a substituted or unsubstituted silyl group, a carboxyl group, a halogen atom, a cyano group, a nitro group, and a hydroxy group, adjacent substituents being bonded to each other to form a saturated or unsaturated cyclic structure or not being bonded to each other.)

23. A method of producing the organic electroluminescence device according to claim 1, using a vapor deposition apparatus that includes: a plurality of vapor deposition sources; and shutters that shield transpiration of a vapor deposition material from the deposition sources, the method comprising steps of:
setting in at least one of the deposition sources a dopant material that forms the luminescent dopant, and setting in at least one of the other deposition sources a host material that forms hosts of the doped regions and a host of the at least one non-doped region;
heating the at least one of the deposition sources in which the dopant material is set and the at least one of the other deposition sources in which the host material is set; and
opening and closing the shutter to form the doped regions and the at least one non-doped region.
